(19) United States
(12) Patent Application Publication
(10) Pub. No.: US 2024/0260271 A1
(43) Pub. Date: Aug. 1, 2024

(54) SEMICONDUCTOR MEMORY DEVICE

(71) Applicant: Kioxia Corporation, Tokyo (JP)

(72) Inventor: Takuya NISHIKAWA, Yokkaichi (JP)

(73) Assignee: Kioxia Corporation, Tokyo (JP)

(21) Appl. No.: 18/525,945

(22) Filed: Dec. 1, 2023

(30) Foreign Application Priority Data
Jan. 26, 2023 (JP) 2023-010516

(51) Int. Cl. H10B 43/27; G11C 16/04; H01L 23/528; H10B 43/10; H10B 43/35

(52) U.S. Cl. CPC H10B 43/27; G11C 16/0483; H01L 23/5283; H10B 43/10; H10B 43/35

(57) ABSTRACT

A semiconductor memory device according to an embodiment includes a first conductor, first to third insulators, a second conductor, and a memory pillar. The first conductor and the first insulator are arranged in a first direction. The second conductor extends in the first direction to penetrate the first conductor and the first insulator. The memory pillar extends in the first direction to penetrate the first conductor and the first insulator, and includes a semiconductor. The second insulator is provided between the first conductor and the second conductor. The third insulator includes a first portion between the second insulator and the first conductor, a portion on a surface on one side of the second insulator in the first direction, and a portion on a surface on the other side of the second insulator in the first direction. The third insulator offers an etching rate smaller than the second insulator.

### CROSS-REFERENCE TO RELATED APPLICATIONS

This application is based upon and claims the benefit of priority from Japanese Patent Application No. 2023-010516, filed Jan. 26, 2023, the entire contents of which are incorporated herein by reference.

### FIELD

Embodiments described herein relate generally to a semiconductor memory device.

### BACKGROUND

A NAND flash memory capable of storing data in a non-volatile manner is known.

### BRIEF DESCRIPTION OF THE DRAWINGS

FIG. 1 shows examples of components of a semiconductor memory device 1 according to a first embodiment, and coupling among the components.

FIG. 2 shows components of a single block BLK included in the semiconductor memory device 1 according to the first embodiment, and coupling among the components.

FIG. 3 shows an example of a plane layout of a part of a memory cell array of the semiconductor memory device 1 according to the first embodiment.

FIG. 4 shows an example of a plane layout of a part of a memory area of a memory cell array 10 included in the semiconductor memory device 1 according to the first embodiment.

FIG. 5 shows an example of a cross-sectional structure of a part of a memory area MA of the semiconductor memory device 1 according to the first embodiment.

FIG. 6 shows an example of a cross-sectional structure of a memory pillar MP in the semiconductor memory device 1 according to the first embodiment.

FIG. 7 shows an example of a plane layout of a part of a hook-up area HA1 of the semiconductor memory device 1 according to the first embodiment.

FIG. 8 is an enlarged view of an area VIII of FIG. 7, showing an example of a cross-sectional structure of the periphery of a contact plug CC.

FIG. 9 shows cross-sectional structures of parts of the memory area MA and the hook-up area HA1 of the semiconductor memory device 1 according to the first embodiment.

FIG. 10 shows a cross-sectional structure of a part of the hook-up area HA1 of the semiconductor memory device 1 according to the first embodiment.

FIG. 11 is an enlarged view of an area XI of FIG. 10, showing an example of a cross-sectional structure of the periphery of the contact plug CC at an HR contacting portion SE.

FIG. 12 is an enlarged view of an area XII of FIG. 9, showing an example of a cross-sectional structure of the periphery of the contact plug CC at an HR non-contacting portion NS.

FIG. 13 shows an example of a cross-sectional structure of the periphery of the contact plug CC in the semiconductor memory device 1 according to the first embodiment.

FIG. 14 shows a flowchart of an example of a manufacturing process of the semiconductor memory device 1 according to the first embodiment.

FIGS. 15 to 40 show examples of cross-sectional structures at respective steps in a manufacturing process of the semiconductor memory device 1 according to the first embodiment.

FIG. 41 shows an example of a cross-sectional structure of the periphery of a contact plug CC in the HR non-contacting portion NSr according to the comparative example of the first embodiment.

FIG. 42 shows an example of a cross-sectional structure of the periphery of a contact plug CC in an HR non-contacting portion NSb according to a first modification of the first embodiment.

FIG. 43 shows an example of a cross-sectional structure of the periphery of a contact plug CC in an HR non-contacting portion NSc according to a second modification of the first embodiment.

FIG. 44 shows an example of a cross-sectional structure of the periphery of a contact plug CC in an HR non-contacting portion NSd_1 according to a third modification of the first embodiment.

FIG. 45 shows an example of a cross-sectional structure of the periphery of a contact plug CC in an HR non-contacting portion NSd_2 according to the third modification of the first embodiment.

FIG. 46 shows an example of a cross-sectional structure of the periphery of a contact plug CC in an HR contacting portion SE according to a fourth modification of the first embodiment.

FIG. 47 shows an example of a cross-sectional structure of the periphery of the contact plug CC in an HR non-contacting portion NS according to the fourth modification of the first embodiment.

### DETAILED DESCRIPTION

A semiconductor memory device according to an embodiment includes a first conductor, a first insulator, a second conductor, a memory pillar, a second insulator, and a third insulator. The first conductor and the first insulator are arranged in a first direction. The second conductor extends in the first direction so as to penetrate the first conductor and the first insulator. The memory pillar extends in the first direction so as to penetrate the first conductor and the first insulator, and includes a semiconductor. The second insulator is provided between the first conductor and the second conductor. The third insulator includes a first portion provided between the second insulator and the first conductor, a portion provided on a surface on one side of the second insulator in the first direction, and a portion provided on a surface on the other side of the second insulator in the first direction. The third insulator offers an etching rate smaller than an etching rate of the second insulator.

Embodiments will now be described with reference to the drawings. With respect to a plurality of components having roughly the same function and configuration in a certain embodiment or over different embodiments, an additional number or character may be added to the end of a reference sign in order to distinguish the components from each other. In an embodiment subsequent to an embodiment that has already been described, matters that differ from those in the already described embodiment will mainly be discussed. The entire description of a particular embodiment also applies to other embodiments unless explicitly mentioned otherwise or obviously excluded.

The drawings are schematic, and the relation between the thickness and the area of a plane of a layer and the ratio of thicknesses of layers may differ from those in actuality. Accordingly, specific thicknesses and dimensions may be determined in consideration of the description to be given below. Moreover, the drawings may include components which differ in relations and/or ratios of dimensions in different drawings. Furthermore, the entire description of a particular embodiment also applies to other embodiments unless explicitly mentioned otherwise or obviously excluded. Each embodiment illustrates a device and a method for materializing the technical idea of that embodiment, and the technical idea of each embodiment does not limit the quality of the material, shape, structure, arrangement of components, etc. to those that will be described below.

Moreover, any step in a flow of a method of an embodiment is not limited to any illustrated order, and can occur in an order different from an illustrated order and/or can occur concurrently with another step.

Hereinafter, embodiments will be described using an orthogonal coordinate system consisting of an x-axis, a y-axis, and a z-axis. In the following description, the expression “below”, its derivatives, and related words refer to the position of smaller coordinates on the z-axis, and the expression “above”, its derivatives, and related words refer to the position of larger coordinates on the z-axis.

In a plan view, hatching may be added in order to improve visibility of the view. Hatching added to the plan view is not necessarily related to a material and/or characteristics of a component to which hatching was added. In a sectional view, components such as insulating layers (interconnect layers), interconnects, contacts, etc. may be omitted in order to improve visibility of the view.

In the present specification, the term “couple” refers to electrical coupling, and does not exclude intervention of, for example, another element. In addition, “electrical coupling” may be performed via an insulator, if the same operation is ensured thereby.

In the specification and the claims, “substantially the same”, “approximately the same”, and “approximately equal” are intended to mean “the same”, but allow for errors due to limitations in manufacturing technology and/or measuring technology.

### <1> First Embodiment

### <1-1> Configuration (Structure)

A semiconductor memory device 1 according to a first embodiment will be described below.

### <1-1-1> Configuration of Semiconductor Memory Device 1

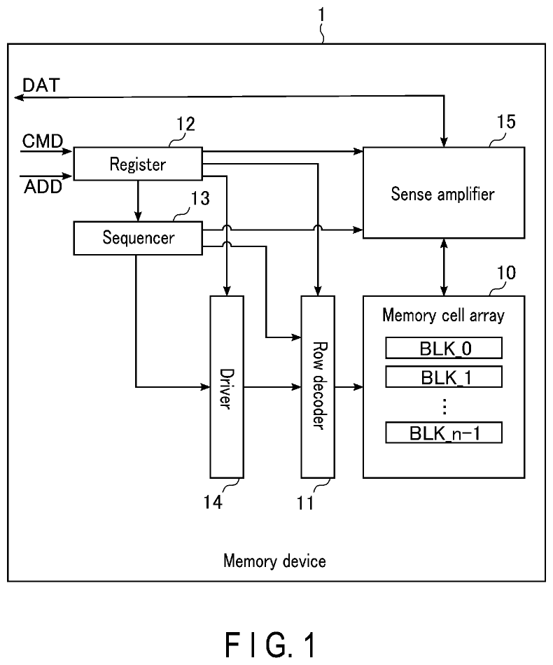

FIG. 1 shows examples of components of a semiconductor memory device 1 according to a first embodiment, and coupling among the components. The semiconductor memory device 1 is a NAND flash memory capable of storing data in a nonvolatile manner. The semiconductor memory device 1 is controlled by an external memory controller. The semiconductor memory device 1 operates based on, for example, a command CMD and address information ADD received from the memory controller. The semiconductor memory device 1 receives data DAT to be written, and outputs data stored in the semiconductor memory device 1. The semiconductor memory device 1 is configured as, for example, a single semiconductor chip.

As shown in FIG. 1, the semiconductor memory device 1 includes components such as a memory cell array 10, a row decoder 11, a register 12, a sequencer 13, a driver 14, and a sense amplifier 15.

The memory cell array 10 includes, for example, a plurality of blocks BLK (BLK_0, BLK_1, . . . ), each of which is used as a unit of data erasure. Each of the blocks BLK includes a set of memory cell transistors MT (not illustrated) capable of storing data in a non-volatile manner. A plurality of source lines SL, a plurality of word lines WL, and a plurality of bit lines BL, etc., which are not illustrated, are coupled to the memory cell array 10. Each memory cell transistor MT is associated with, for example, a single bit line BL and a single word line WL. A detailed configuration of the memory cell array 10 will be described later.

The row decoder 11 is a circuit for selecting a block BLK. The row decoder 11 transfers voltages supplied from the driver 14 to a single block BLK selected based on a block address received from the register 12.

The register 12 is a circuit that holds a command CMD and address information ADD received by the semiconductor memory device 1 from, for example, a memory controller. The command CMD instructs the sequencer 13 to perform various operations including data read, data write, and data erase. The address information ADD designates a target of access in the memory cell array 10.

The sequencer 13 is a circuit that controls an operation of the entirety of the semiconductor memory device 1. The sequencer 13 controls the row decoder 11, the driver 14, and the sense amplifier 15 based on the command CMD received from the register 12 to perform various operations including data read, data write, and data erase.

The driver 14 is a circuit that generates a plurality of voltages of different magnitudes, and applies various voltages to be used in an operation of the semiconductor memory device 1 to some components. The driver 14 supplies voltages selected from among the generated voltages based on control performed by the sequencer 13 and the address information ADD to the row decoder 11.

The sense amplifier 15 is a circuit that outputs a signal based on data stored in the memory cell array 10. The sense amplifier 15 senses a state of the memory cell transistor MT and generates read data based on the sensed state, or transfers write data to the memory cell transistor MT.

### <1-1-2> Circuit Configuration of Memory Cell Array 10

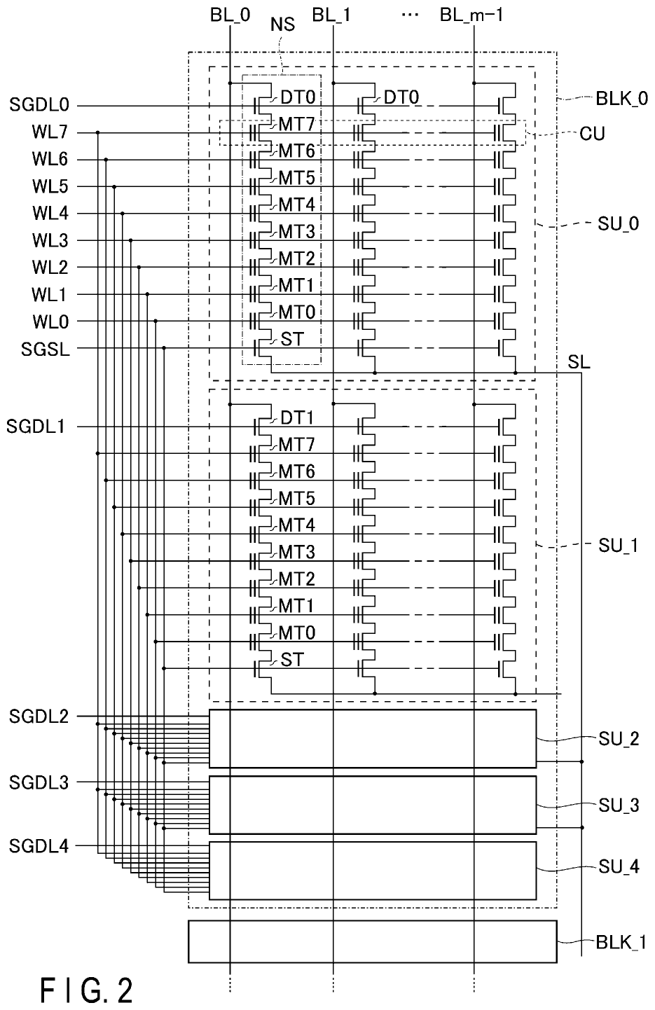

FIG. 2 shows components of a single block BLK included in the semiconductor memory device 1 according to the first embodiment, and coupling among the components. A plurality of blocks BLK, for example, all of the blocks BLK, include the components and coupling that are illustrated in FIG. 2.

A single block BLK includes a plurality of string units SU. The number of blocks BLK included in the semiconductor memory device 1 and the number of string units SU in each block BLK can be designed to be any number. The description to be given below is based on an example in which each block BLK includes five string units SU_0 to SU_4.

Each of m bit lines BL_0 to BL_m−1 is coupled to a single NAND string NS from each of the string units SU_0 to SU_4 in each of the blocks BLK. m is a positive integer.

Each of the NAND strings NS includes a single select gate transistor ST, a plurality of memory cell transistors MT, and a single select gate transistor DT (DT0, DT1, DT2, DT3, or DT4). FIG. 2 is based on an example in which each NAND string NS includes eight memory cell transistors MT0 to MT7.

The memory cell transistor MT is an element that includes a control gate electrode and a charge storage film insulated from the periphery, and stores data in a non-volatile manner based on a charge amount in the charge storage film. Each of the select gate transistors ST and DT is used to select a string unit SU during various operations.

The select gate transistor ST, the memory cell transistors MT, and the select gate transistor DT are coupled in series in this order between a source line SL and a single bit line BL.

A plurality of NAND strings NS respectively coupled to a plurality of different bit lines BL configure a single string unit SU. In each of the string units SU, the control gate electrodes of the memory cell transistors MT0 to MT7 are respectively coupled to word lines WL0 to WL7. A group of memory cell transistors MT that share the word line WL in a single string unit SU will be referred to as a “cell unit CU”.

The select gate transistors DT0 to DT4 respectively belong to the string units SU_0 to SU_4. In FIG. 2, the select gate transistors DT2 to DT4 are not illustrated. A gate of the select gate transistor DT0 of each of the plurality of NAND strings NS of the string unit SU_0 is coupled to a select gate line SGDL0. Similarly, gates of the select gate transistors DT1, DT2, DT3, and DT4 of each of the plurality of NAND strings NS of each of the string units SU_1, SU_2, SU_3, and SU_4 are respectively coupled to select gate lines SGDL1, SGDL2, SGDL3, and SGDL4.

A gate of the select gate transistor ST is coupled to a select gate line SGSL.

The components of the block BLK and coupling among the components of the semiconductor memory device 1 according to the first embodiment are not limited to the example described above. For example, the number of memory cell transistors MT and select gate transistors ST and DT included in each NAND string NS may be designed to be any number.

### <1-1-3> Plane Structure of Memory Cell Array 10

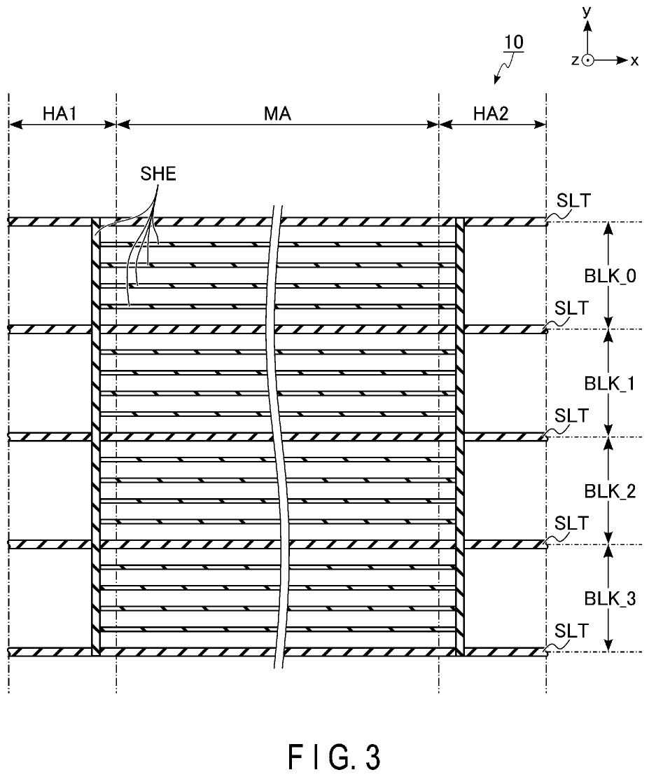

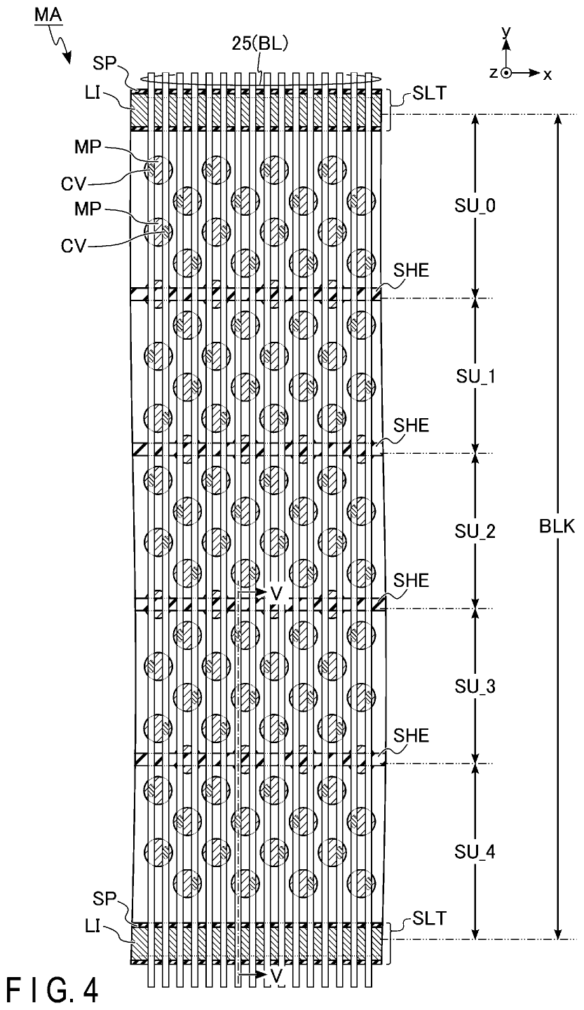

FIG. 3 shows an example of a plane layout of a part of a memory cell array 10 of the semiconductor memory device 1 according to the first embodiment. FIG. 4 shows an example of a plane layout of a part of a memory area of a memory cell array 10 included in the semiconductor memory device 1 according to the first embodiment. FIG. 3 shows, along an xy plane, an area where four blocks BLK_0 to BLK_3 are formed. The structure shown in FIG. 3 is repeatedly provided along a y direction.

As shown in FIG. 3, the memory cell array 10 includes a memory area MA and hook-up areas HA1 and HA2. The hook-up area HA1, the memory area MA, and the hook-up area HA2 are arranged in this order along an x direction. In the memory cell array 10, a plurality of members SLT and SHE are provided.

The memory area MA includes a plurality of NAND strings NS. In each of the hook-up areas HA1 and HA2, contact plugs are provided so as to be coupled to a stacked structure in which memory cell transistors are formed.

The plurality of members SLT extend along the x direction, and are arranged along the y direction. Each of the members SLT is located at a boundary between adjacent blocks BLK. The members SLT cross the memory area MA and the hook-up areas HA1 and HA2. Each of the members SLT has, for example, a structure in which an insulator spacer and a plate-shaped contact (or a plate-shaped insulator) are embedded. Each of the members SLT divides stacked structures that are adjacent with the member SLT interposed therebetween.

In the plane layout of the memory cell array 10 described above, each area sectioned by the members SLT functions as a single block BLK.

Also, as shown in FIG. 4, each of the area sectioned by the members SLT and SHE and the area sectioned by the members SHE and SHE functions as a single string unit SU. Specifically, a plurality of members SHE are disposed, for example, between string units SU0 and SU1 adjacent to each other in the Y direction, between the string units SU1 and SU2, between the string units SU2 and SU3, and between the string units SU3 and SU4. In the memory cell array 10, a layout similar to the layout shown in FIG. 4, for example, is repeatedly disposed in the y direction.

The plurality of members SHE extend along the x direction, and are arranged along the y direction. A plurality of members SHE are located between every two adjacent members SLT. FIG. 4 shows an example in which four members SHE are provided. Each of the members SHE intersects the memory area MA along the x direction. Both ends of each of the members SHE are respectively located in the hook-up areas HA1 and HA2. Also, as shown in FIG. 3, both ends of the plurality of the members SHE are coupled with each other and with a pair of the members SLT on both sides of the plurality of members SHE in the y direction interposing these members SHE. Each of the members SHE includes, for example, an insulator. Each of the members SHE divides select gate lines SGDL that are adjacent with the member SHE interposed therebetween. In each area sectioned by the members SLT and SHE, a single string unit SU is formed.

A plane layout of the memory cell array 10 included in the semiconductor memory device 1 according to the first embodiment is not limited to the layout described above. For example, the number of members SHE disposed between adjacent members SLT may be designed to be any number. Moreover, the number of string units SU formed between adjacent members SLT may be changed based on the number of members SHE disposed between adjacent members SLT.

FIG. 4 is an enlarged view of an area including a single block BLK (i.e., string units SU0 to SU4) and two members SLT interposing the block BLK. As shown in FIG. 4, the memory cell array 10 includes a plurality of memory pillars MP, a plurality of contacts CV, a plurality of members SLT and SHE, and a plurality of conductors 25 in the memory area MA. Each of the members SLT includes a contact LI and a spacer SP.

Each memory pillar MP has a structure in which a plurality of memory cell transistors MT are formed inside. Each memory pillar MP includes one or more semiconductors and one or more insulators. The memory pillar MP functions as a single NAND string NS. A plurality of memory pillars MP are distributed in a staggered array in an area between two members SLT. That is, a plurality of memory pillars MP are disposed in a plurality of columns along the y direction. The columns of the memory pillars MP are arranged in the x direction. In each column, the memory pillars MP are arranged along the y direction. Two columns include memory pillars MP disposed in a zigzag manner in the y direction. That is, memory pillars MP belonging to two adjacent columns are located at different y-direction coordinates. On the other hand, y-direction coordinates of memory pillars MP in two columns that sandwich another column are substantially the same.

The disposition of the memory pillars MP that has been described with respect to the columns is applicable to a description with respect to the rows. The description with respect to the rows corresponds to a description in which the “column” in the above description is replaced with a “row”, and the “y direction” is replaced with the “x direction”.

In the example of FIG. 4, 24 rows of memory pillars MP are provided in an area between two adjacent members SLT in the xy plane. It is to be noted that the number and disposition of the memory pillars MP between adjacent members SLT are not limited thereto, and may be suitably varied.

As an example, a single member SHE overlaps each of the fifth, the tenth, the fifteenth, and the twentieth memory pillars MP, counting from the upper side (+y side) of FIG. 4.

Each conductor 25 functions as a single bit line BL. The conductors 25 extend in the y direction, and are arranged along the x direction. Each conductor 25 is disposed so as to overlap at least one memory pillar MP in each string unit SU. In the example of FIG. 4, a disposition is shown in which two conductors 25 overlap a single memory pillar MP. Each memory pillar MP is electrically coupled to one of the conductors 25 that overlap the memory pillar MP via a contact CV. A single contact CV is coupled to each conductor 25 in each of the areas sectioned by two of the members SLT and SHE.

For example, a contact CV between a bit line BL and a memory pillar MP that is in contact with a member SHE is omitted. In other words, a contact CV between a bit line BL and a memory pillar MP that is in contact with two different select gate lines SGDL is omitted. The number of bit lines BL that overlap each memory pillar MP may be designed to be any number.

The contact LI is formed of a conductor. The contact LI has a plate-like shape extending along an xz plane. The spacer SP is an insulator located on a side surface of the contact LI so as to, for example, cover a side surface of the contact LI. Each member SLT divides stacked interconnects (e.g., word lines WL) that are adjacent to each other with the member SLT interposed therebetween.

### <1-1-4> Cross-Sectional Structure of Memory Area

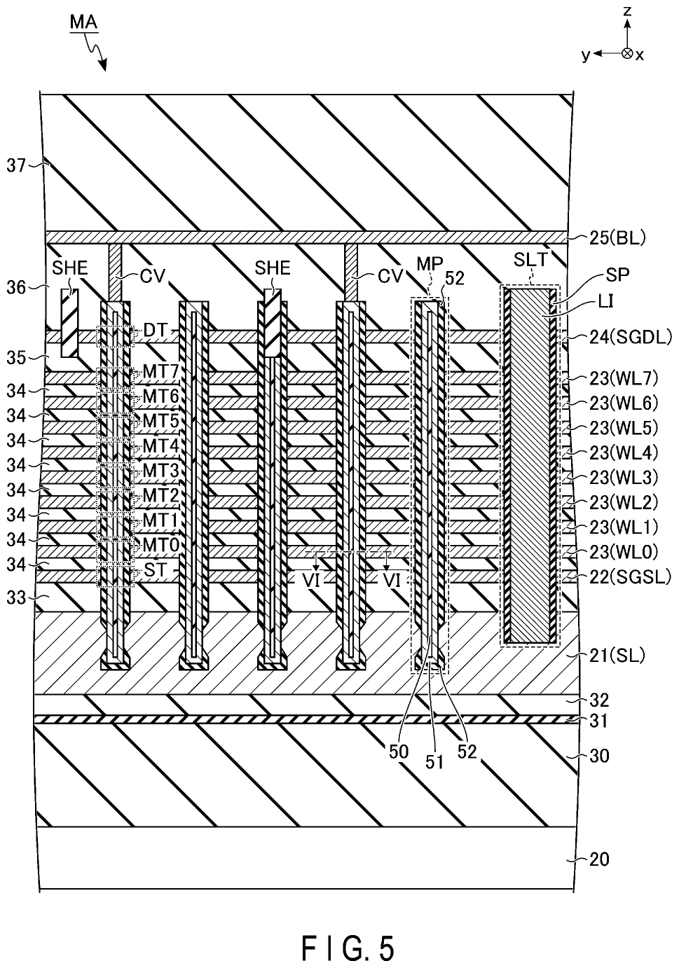

FIG. 5 shows an example of a cross-sectional structure of a part of a memory area MA of the semiconductor memory device 1 according to the first embodiment. Specifically, FIG. 5 shows a cross section taken along line V-V of FIG. 4.

As shown in FIG. 5, the memory cell array 10 further includes, for example, a substrate 20, conductors 21 and 22, a plurality of conductors 23, conductors 24 and 25, and insulators 30 to 37 in the memory area MA. In the example of FIG. 5, eight conductors 23 are provided. The insulators 30 to 37, excluding the insulator 31, include, for example, silicon oxide (SiO₂).

The substrate 20 is, for example, a substrate of a p-type semiconductor. On an upper surface of the substrate 20, the insulator 30 is located. In the substrate 20 and the insulator 30, a non-illustrated circuit is provided. The circuit is, for example, the row decoder 11 and/or the sense amplifier 15, and includes a non-illustrated transistor.

The insulator 31 is located on an upper surface of the insulator 30. The insulator 31 inhibits, for example, hydrogen from entering a transistor included in the substrate 20 and the insulator 30, from a structure above the insulator 31. The insulator 31 may be referred to as a “barrier film”. The insulator 31 includes, for example, silicon nitride (SiN).

The insulator 32 is located on an upper surface of the insulator 31.

The conductor 21 is located on an upper surface of the insulator 32. The conductor 21 has a plate-like shape extending along the xy plane. The conductor 21 functions as at least a part of the source line SL. The conductor 21 includes, for example, silicon (Si) doped with phosphorus (P), a metal material, etc.

The insulator 33 is located on an upper surface of the conductor 21.

The conductor 22 is located on an upper surface of the insulator 33. The conductor 22 has a plate shape extending along the xy plane. The conductor 22 functions as at least a part of the select gate line SGSL. The conductor 22 includes, for example, tungsten (W) or molybdenum (Mo).

The plurality of insulators 34 and the plurality of conductors 23 are located alternately one by one along a z direction on an upper surface of the conductor 22. Accordingly, the conductors 23 are arranged along the z direction so as to be separated from each other or to be spaced apart from each other. Each of the insulators 34 and the conductors 23 has a plate-like shape extending along, for example, the xy plane. The conductors 23 respectively function as the word lines WL0 to WL7 in order from a side of the substrate 20. The conductors 23 include, for example, tungsten or molybdenum.

The insulator 35 is located on an upper surface of an uppermost conductor 23.

The conductor 24 is located on an upper surface of the insulator 35. The conductor 24 has a plate-like shape extending along the xy plane. The conductor 24 functions as at least a part of the select gate line SGDL. The conductors 24 include, for example, tungsten or molybdenum.

The insulator 36 is located on an upper surface of the conductor 24.

The conductor 25 is located on an upper surface of the insulator 36. The conductor 25 has, for example, a linear shape extending in the y direction. The conductor 25 functions as at least a part of a single bit line BL. A conductor 25 is further provided on a yz plane that is different from a yz plane shown in FIG. 5, and the conductors 25 are thus arranged along the x direction so as to be spaced apart from each other. The conductor 25 includes, for example, copper (Cu).

The insulator 37 is located on an upper surface of the conductor 25. The insulator 37 may include one or more interconnects for coupling the memory cell array 10 with the row decoder 11 and/or the sense amplifier 15, etc.

Each of the memory pillars MP has a pillar shape extending in the z direction. Each memory pillar MP is located in a stacked structure including the insulators 33 to 35 and the conductors 22 to 24, so as to penetrate or pass through the insulators 33 to 35 and the conductors 22 to 24. An upper surface of the memory pillar MP is located in the insulator 36. A lower surface of the memory pillar MP is located in the conductor 21. A portion where the memory pillar MP and the conductor 22 intersect each other functions as the select gate transistor ST. A portion where the memory pillar MP and one of the conductors 23 intersect each other functions as a single memory cell transistor MT. A portion where the memory pillar MP and the conductor 24 intersect each other functions as the select gate transistor DT.

The memory pillar MP includes, for example, a core 50, a semiconductor 51, and a layer stack 52. The core 50 is formed of an insulator, and includes, for example, silicon oxide. The core 50 has a pillar shape extending in the z direction. The core 50 is located at a central part of the memory pillar MP. An upper surface of the core 50 is located above a layer in which the conductor 24 is provided. A lower surface of the core 50 is located in the conductor 21.

The semiconductor 51 includes, for example, silicon. The semiconductor 51 covers, for example, a surface of the core 50. A part of the semiconductor 51 is, for example, in contact with the conductor 21 at its side surface.

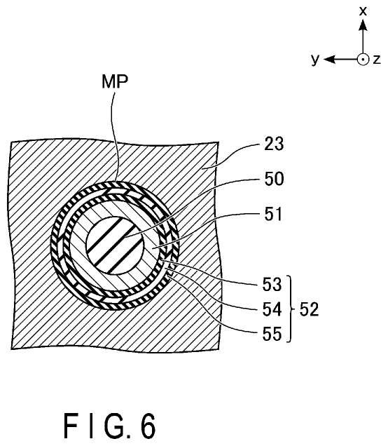

The layer stack 52 covers a side surface and a lower surface of the semiconductor 51, excluding a portion at which the semiconductor 51 and the conductor 21 are in contact with each other. That is, the layer stack 52 has an opening in the conductor 21, and the conductor 21 is partially located in the opening. Details of the layer stack 52 will be described later with reference to FIG. 6.

The member SLT divides the conductors 22 to 24 in the y direction. An upper surface of the contact LI of the member SLT is located above the upper surface of the memory pillar MP. A lower surface of the contact LI is in contact with the conductor 21. The contact LI functions as a part of the source line SL. The spacer SP is located at least between the contact LI and the conductors 22 to 24, and isolates and insulates the contact LI from the conductors 22 to 24. It is to be noted that the member SLT may have a structure in which a contact LI is not provided and an insulator is embedded over the entirety of the member SLT.

The member SHE divides at least the conductor 24 in the y direction. An upper surface of the member SHE is located in the insulator 36. A lower surface of the member SHE is located in the insulator 35. The member SHE includes, for example, an insulator such as silicon oxide. Upper ends of the members SHE and SLT may be either aligned or not aligned.

As described above, each memory pillar MP is coupled to a corresponding one of the conductors 25 via a contact CV. Specifically, a columnar contact CV is provided on an upper surface of the semiconductor 51. In the illustrated area, two contacts CV respectively coupled to two of the five memory pillars MP are shown. Each contact CV is coupled to a corresponding one of the conductors 25 in each space sectioned by the members SLT and SHE. That is, a memory pillar MP provided between adjacent members SLT and SHE and a memory pillar MP provided between two adjacent members SHE are electrically coupled to the conductor 25. A contact CV is coupled in an unillustrated area to each of the memory pillars MP that do not overlap a member SHE and to which a contact CV is not coupled in the illustrated area.

Here, a high dielectric constant insulator that functions as a block insulating film may be provided in the periphery of the conductors 22 to 24. An example in which a high dielectric constant insulator is provided in the periphery of the conductors 22 to 24 will be described later in a modification.

FIG. 6 shows an example of a cross-sectional structure of a memory pillar MP in the semiconductor memory device 1 according to the first embodiment. Specifically, FIG. 6 shows a cross section taken along line VI-VI of FIG. 5. FIG. 6 shows a cross-sectional structure of a memory pillar MP in a layer that is parallel to the surface of the substrate 20 and includes the conductor 23. As shown in FIG. 6, the layer stack 52 includes, for example, a tunnel insulator 53, a charge storage film 54, and a block insulator 55.

In a cross section including the conductor 23, the core 50 is located at a central part of the memory pillar MP. The semiconductor 51 surrounds a side surface of the core 50. The tunnel insulator 53 surrounds a side surface of the semiconductor 51. The charge storage film 54 surrounds a side surface of the tunnel insulator 53. The block insulator 55 surrounds a side surface of the charge storage film 54. The conductor 23 surrounds a side surface of the block insulator 55. Both of the tunnel insulator 53 and the block insulator 55 include, for example, silicon oxide. The charge storage film 54 includes, for example, silicon nitride.

In the memory pillar MP, the semiconductor 51 functions as a channel (a current path) of the memory cell transistors MT0 to MT7 and the select gate transistors DT and ST. The semiconductor memory device 1 is capable of letting a current flow via a memory pillar MP between the bit line BL and the contact LI by operating the memory cell transistors MT0 to MT7 and the select gate transistors DT and ST. This allows each of the memory pillars MP to function as a single NAND string NS.

### <1-1-5> Structure of Hook-Up Area

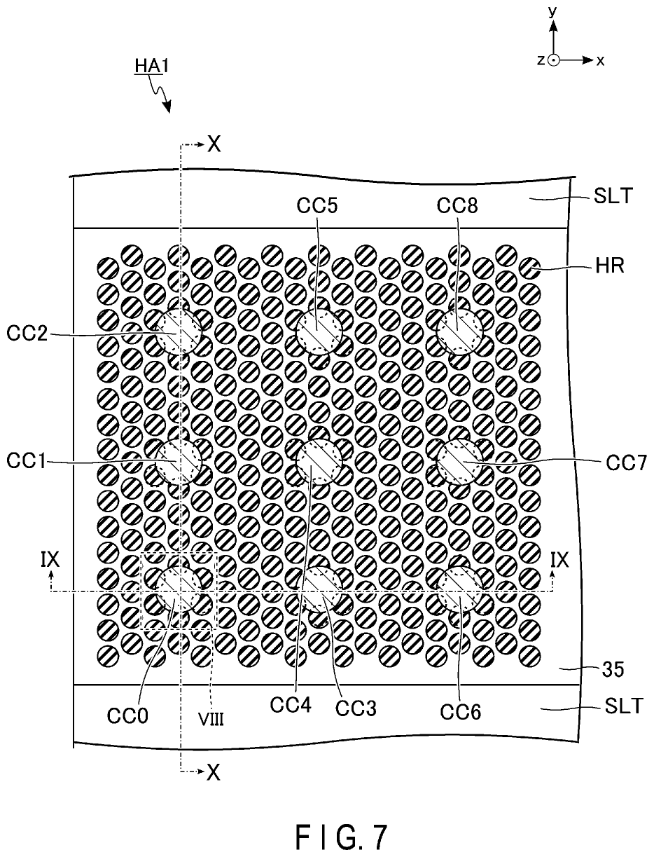

FIG. 7 shows an example of a plane layout of a part of a hook-up area HA1 of the semiconductor memory device 1 according to the first embodiment. In FIG. 7, a part of an area between two members SLT is shown along the xy plane. FIG. 7 shows a layout in a case where a layer including the insulator 35 is viewed from above in the z direction.

As shown in FIG. 7, the hook-up area HA1 includes a plurality of support pillars HR and a plurality of contact plugs CC.

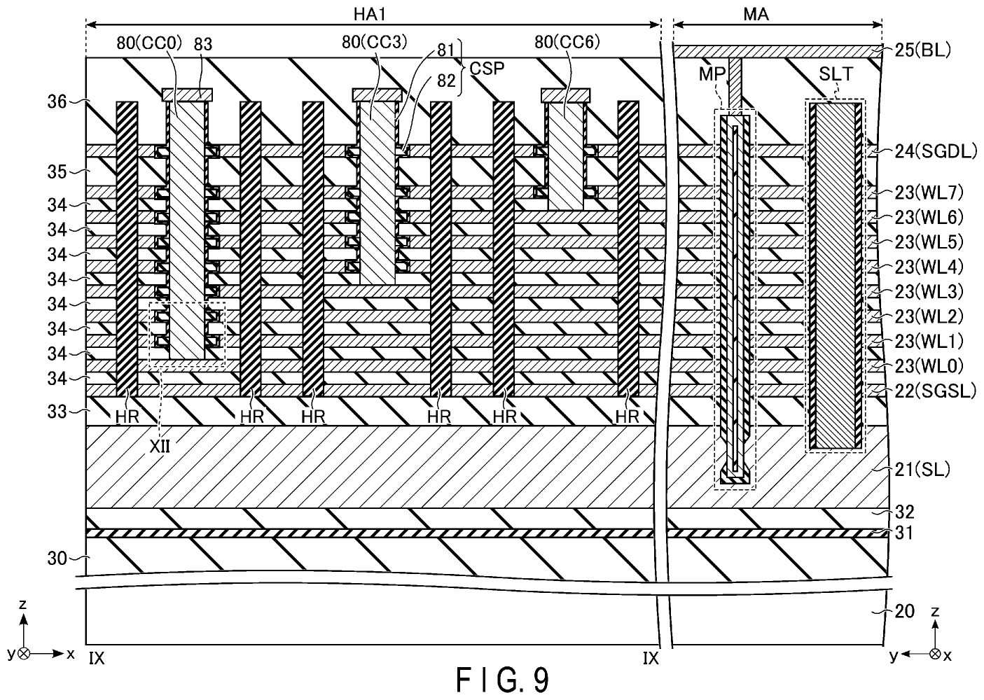

The support pillars HR are distributed over the entirety of the hook-up area HA1. The support pillars HR are formed of, for example, an insulator such as silicon oxide. Each support pillar HR has a pillar shape, and extends in the z direction. The support pillar HR extends from a layer of the insulator 36 to a layer of the conductor 22, as will be described later with reference to FIG. 9.

In FIG. 7, an example is shown in which the support pillars HR partially overlap the contact plugs CC. Of the support pillars HR that overlap a contact plug CC, a portion that overlaps the contact plug CC is, at its upper surface, in contact with a lower surface of the contact plug CC, and is not located in the insulator 36.

As an example, the support pillars HR in FIG. 7 are distributed in a staggered array. Also, in the example of FIG. 7, support pillars HR overlapping a contact plug CC are not provided so as to overlap the center of the contact plug CC but to be deviated from the center of the contact plug CC. The layout of the support pillars HR is not limited to the structure described above. For example, the support pillars HR may have a structure not overlapping a contact plug CC. Such an example will be described later.

The contact plugs CC configure a plurality of rows extending along the x direction. FIG. 7 shows, as an example, three rows of contact plugs CC arranged in the y direction. A row of contact plugs CC may be referred to as a “contact plug set”. FIG. 7 shows an example in which x-direction coordinates of two adjacent rows of contact plugs CC are substantially the same. That is, an x-direction coordinate of each of the contact plugs CC in one of two adjacent rows is substantially the same as an x-direction coordinate of the corresponding contact plug CC in the other row.

The contact plugs CC may be distributed in a staggered array. That is, two adjacent rows of contact plugs CC may be shifted from each other. In other words, two rows of contact plugs CC may be disposed in a zigzag manner in the x direction.

The disposition of the contact plugs CC that have been described with respect to the rows is applicable to a description with respect to the columns. The description with respect to the columns corresponds to a description in which the “row” in the above description is replaced with a “column”, and the “x direction” is replaced with the “y direction”.

Lower surfaces of the respective contact plugs CC are in contact with upper surfaces of different conductors 23. A specific example will be described below.

Contact plugs CC in a row with the smallest y-coordinate (a lowermost row) in FIG. 7 will be referred to as “CC0”, “CC3”, and “CC6” in increasing order in the x-coordinate (in order from left to right). A lower surface of the contact plug CC0 is in contact with an upper surface of the conductor 23 that functions as the word line WL0. A lower surface of the contact plug CC3 is in contact with an upper surface of the conductor 23 that functions as the word line WL3. A lower surface of the contact plug CC6 is in contact with an upper surface of the conductor 23 that functions as the word line WL6.

Contact plugs CC in a row with the second smallest y-coordinate (a second lowermost row) will be referred to as “CC1”, “CC4”, and “CC7” in increasing order of the x-coordinate (in order from left to right). A lower surface of the contact plug CC1 is in contact with an upper surface of the conductor 23 that functions as the word line WL1. A lower surface of the contact plug CC4 is in contact with an upper surface of the conductor 23 that functions as the word line WL4. A lower surface of the contact plug CC7 is in contact with an upper surface of the conductor 23 that functions as the word line WL7.

Contact plugs CC in a row with the largest y-coordinate (an uppermost row) will be referred to as “CC2”, “CC5”, and “CC8” in increasing order of the x-coordinate (in order from left to right). A lower surface of the contact plug CC2 is in contact with an upper surface of the conductor 23 that functions as the word line WL2. A lower surface of the contact plug CC5 is in contact with an upper surface of the conductor 23 that functions as the word line WL5. A lower surface of the contact plug CC8 is in contact with, for example, an upper surface of the conductor 22 that functions as the select gate line SGSL.

As described with reference to FIG. 5, the conductors 23 that function as different word lines WL are located at different heights or in different layers. Accordingly, a position of a lower surface of a contact plug CC is based on a position of a conductor 23 that the contact plug CC is in contact with.

A non-illustrated spacer CSP is provided in the periphery of the contact plug CC. The spacer CSP insulates the contact plug CC from the conductors 23 (and 24) located above the conductor 23 or 22 that the contact plug CC is in contact with at its lower surface. The spacer CSP will be described later.

As described above with reference to FIG. 7, of a support pillar HR that at least partially overlaps a contact plug CC, an upper surface of a portion that overlaps the contact plug CC is in contact with a lower surface of the contact plug CC. Accordingly, a support pillar HR that partially overlaps a contact plug CC includes a step at a position of a lower surface of the contact plug CC that the support pillar HR partially overlaps.

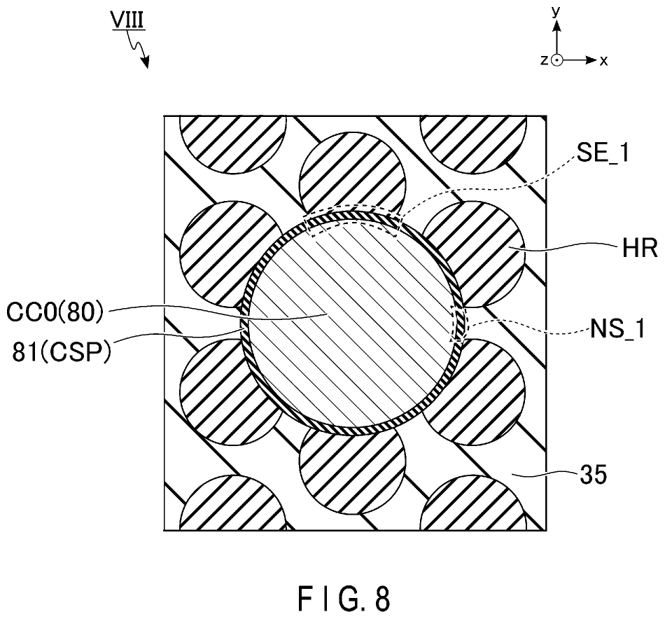

FIG. 8 is an enlarged view of an area VIII of FIG. 7, showing an example of a cross-sectional structure of the periphery of a contact plug CC. That is, FIG. 8 shows a cross-sectional structure of a spacer CSP and a contact plug CC0 in a layer that is parallel to the surface of the substrate 20 and that includes the insulator 35. The contact plug CC includes a conductor 80.

As described above, a spacer CSP is provided in the periphery of the contact plug CC (conductor 80) in the xy plane. That is, the spacer CSP covers a side surface of the conductor 80. In the example of FIG. 8, the contact plug CC partially overlaps the support pillars HR in an xy plane view. That is, the spacer CSP includes both a portion overlapping the support pillars HR and a portion not overlapping the support pillars HR.

The portion of the spacer CSP and the contact plug CC overlapping the support pillars HR may be hereinafter referred to as an “HR contacting portion SE”. The portion of the spacer CSP and the contact plug CC not overlapping the support pillars HR may be hereinafter referred to as an “HR non-contacting portion NS”.

At an unillustrated position in the z direction of the contact plug CC0, each of the structure of the spacer CSP in a layer that is parallel to the surface of the substrate 20 and that includes the insulator 34 and a structure of the spacer CSP in a layer that is parallel to the surface to the substrate 20 and includes the insulator 36 is similar to the structure of the spacer CSP in a layer that is parallel to the surface of the substrate 20 and that includes the insulator 35. Hereinafter, a portion of the HR contacting portion SE that intersects the insulators 34 to 36 may be referred to as an “HR contacting portion SE_1”. A portion of the HR non-contacting portion NS that intersects the insulators 34 to 36 may be hereinafter referred to as an “HR non-contacting portion NS_1”. Each of the insulators 34 to 36 may be referred to as an “interlayer insulating film”.

At an unillustrated position in the z direction, the structure of the spacer CSP in a layer that is parallel to the surface of the substrate 20 and includes the conductor 23 and a structure of the spacer CSP in a layer that is parallel to the surface to the substrate 20 and includes the conductor 24 are similar to each other. Accordingly, a portion of the HR contacting portion SE that intersects the conductors 23 to 24 may be referred to as an “HR contacting portion SE_2”. A portion of the HR non-contacting portion NS that intersects the conductors 23 to 24 may 24 may be hereinafter referred to as an “HR non-contacting portion NS_2”.

That is, FIG. 8 shows a cross-sectional structure of the spacer CSP and the contact plug CC at the HR contacting portion SE_1 and the HR non-contacting portion NS_1. As shown in FIG. 8, the HR contacting portion SE_1 and the HR non-contacting portion NS_1 include the first spacer 81. That is, the spacer CSP includes a first spacer 81 at the portion intersecting the insulators 34 to 36. The first spacer 81 covers a side surface of the conductor 80. A side surface of the HR contacting portion SE_1 (first spacer 81) is covered with the support pillar HR. A side surface of the HR non-contacting portion NS_1 (first spacer 81) is covered with the insulator 35. A side surface of the support pillar HR other than a portion overlapping the contact plug CC is covered with the insulator 35.

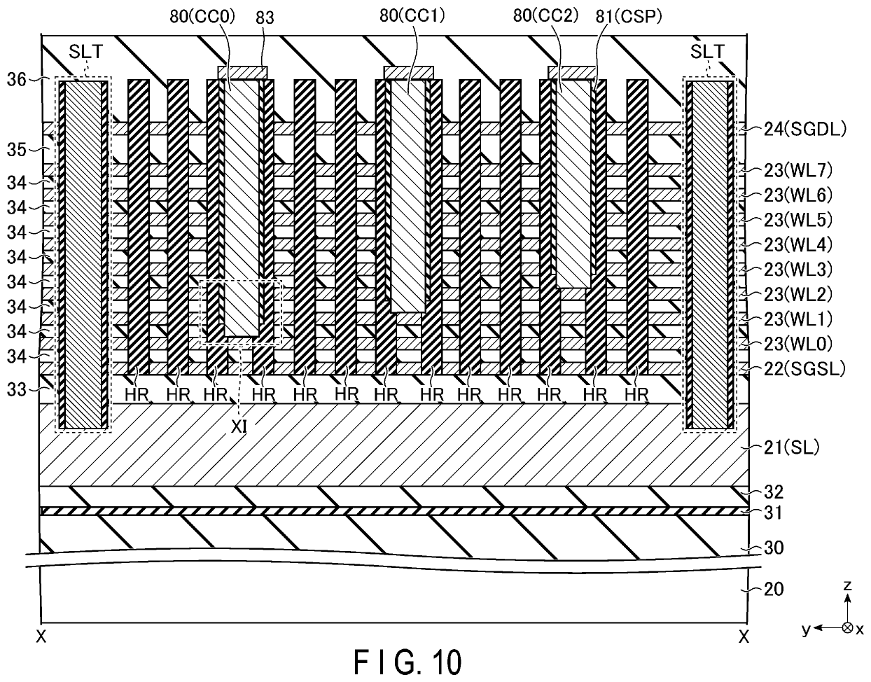

FIGS. 9 and 10 show cross-sectional structures of parts of the memory area MA and the hook-up area HA1 of the semiconductor memory device 1 according to the first embodiment. Specifically, FIG. 9 shows a cross section of the hook-up area HA1 taken along line IX-IX of FIG. 7, and also shows a part of the memory area MA shown in FIG. 5. FIG. 10 shows a cross section of the hook-up area HA1 taken along line X-X of FIG. 7. FIG. 9 is an example of a cross-sectional structure of an HR non-contacting portion NS. FIG. 10 is an example of a cross-sectional structure of an HR contacting portion SE.

As shown in FIGS. 9 and 10, each of the contact plugs CC (conductors 80) penetrates the conductor 24 and the insulator 35. Some of the contact plugs CC further penetrate one or more conductors 23 and one or more insulators 34.

As described with reference to FIG. 7, lower surfaces of different contact plugs CC are in contact with different conductors 23. A lower surface of the contact plug CC0 is in contact with an upper surface of the conductor 23 that functions as the word line WL0. In other words, a surface on one side of the contact plug CC0 in the z direction is in contact with a surface on the other side of the conductor 23 that functions as the word line WL0 in the z direction. At this time, the contact plug CC0 penetrates the conductors 23 and the insulators 34 located above the conductor 23 that functions as the word line WL0. On the other hand, the memory pillar MP also penetrates the conductor 23 that functions as the word line WL0.

Similarly, a lower surface of the contact plug CC1 is in contact with an upper surface of the conductor 23 that functions as the word line WL1. A lower surface of the contact plug CC2 is in contact with an upper surface of the conductor 23 that functions as the word line WL2. A lower surface of the contact plug CC3 is in contact with an upper surface of the conductor 23 that functions as the word line WL3. A lower surface of the contact plug CC6 is in contact with an upper surface of the conductor 23 that functions as the word line WL6.

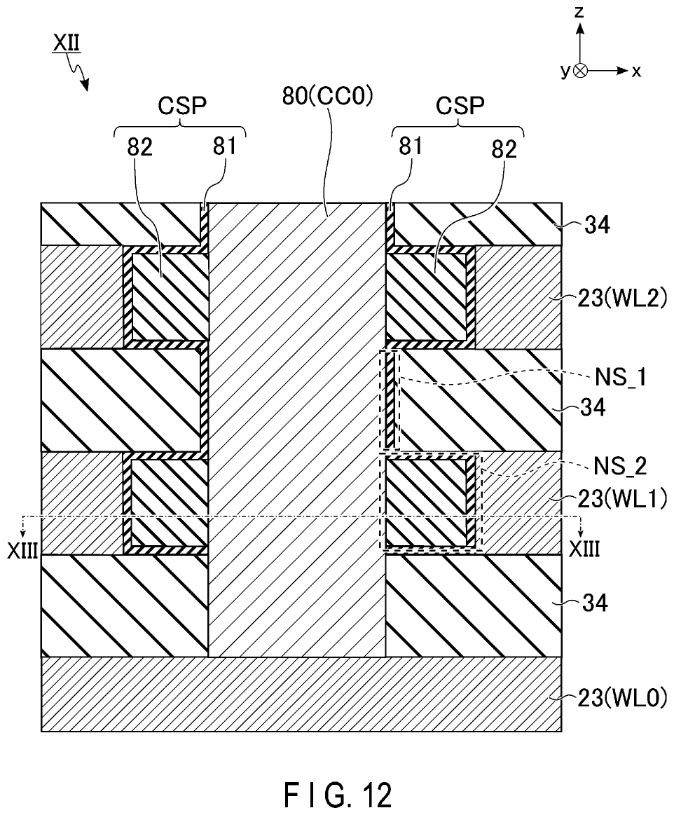

As shown in FIG. 9, the HR non-contacting portion NS includes a first spacer 81 and a second spacer 82. The second spacer 82 is provided at the HR non-contacting portion NS_2. The HR non-contacting portion NS_1 does not include a second spacer 82. Ideally, the first spacer 81 is provided over the entirety of the HR non-contacting portions NS_1 and NS_2. Details will be described later with reference to FIG. 12.

As shown in FIG. 10, the HR contacting portion SE includes a first spacer 81. The first spacer 81 is provided on a side surface of the conductor 80. That is, at the HR contacting portion SE, the first spacer 81 is provided between the conductor 80 and the support pillar HR.

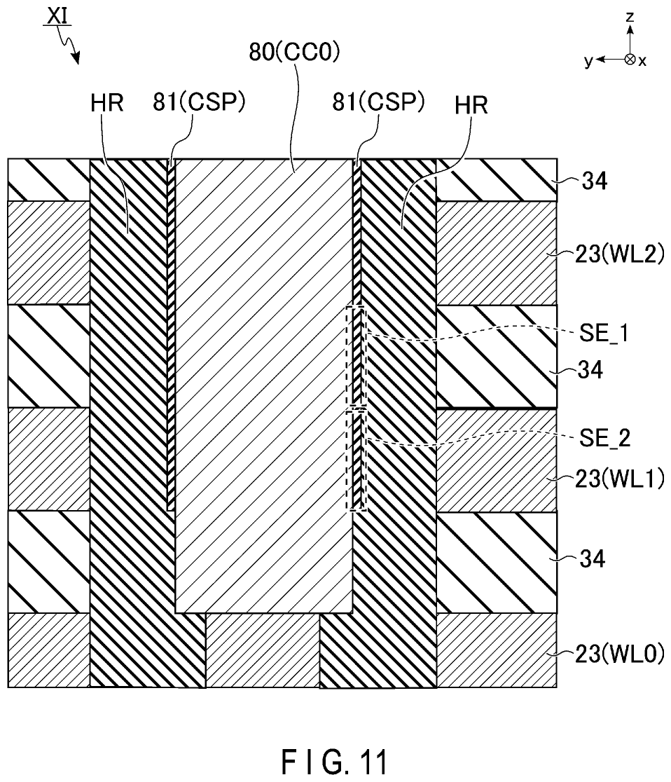

In this manner, the configuration and structure of the spacer CSP (HR contacting portion SE) in the cross section shown in FIG. 10 differs from the configuration and structure of the spacer CSP (HR non-contacting portion NS) in the cross section shown in FIG. 9. Details of the spacer CSP will be described later with reference to FIGS. 11 and 12. As described above, the spacer CSP insulates the conductor 80 from the conductors 23 and 24 located above the conductor 22 or 23 that the conductor 80 is in contact with at its lower surface.

A conductor 83 is provided on the upper surface of the contact plug CC.

In each contact plug CC described above, the conductor 80 is used as a hook-up line for applying a voltage to each of the memory cell transistors MT0 to MT7 and the select gate transistors ST and DT.

FIG. 11 is an enlarged view of an area XI of FIG. 10, showing an example of a cross-sectional structure of the periphery of the contact plug CC at an HR contacting portion SE. The spacer CSP covers the periphery of the conductor 80 in the xy plane, excluding a layer including the insulator 34 on an upper surface of the conductor 23 with which a lower surface of the conductor 80 is in contact. As described with reference to FIG. 10, the HR contacting portion SE includes a first spacer 81. The first spacer 81 is provided between the conductor 80 and the support pillar HR. On a side surface of the support pillar HR deviated from the HR contacting portion SE, a layer stack of the interlayer insulating film and the conductors 23 and 22 (hereinafter also referred to as a “layer stack body”) is located.

That is, the HR contacting portion SE does not include a second spacer 82. The first spacer 81 has a shape extending in the z direction. The structure and configuration of the HR contacting portion SE do not depend on the z direction. That is, the structure and configuration of the HR contacting portion SE_1 are similar to those of the HR contacting portion SE_2.

Here, the first spacer 81 includes, for example, silicon oxide. The silicon oxide of the first spacer 81 is formed by, for example, forming silicon nitride and replacing nitrogen in the silicon nitride with oxygen by means of oxygen radicals.

FIG. 12 is an enlarged view of an area XII of FIG. 9, showing an example of a cross-sectional structure of the periphery of the contact plug CC at the HR non-contacting portion NS. The spacer CSP covers the periphery of the conductor 80 in the xy plane, excluding a layer including the insulator 34 on an upper surface of the conductor 23 with which a lower surface of the conductor 80 is in contact. As described with reference to FIG. 9, the HR non-contacting portion NS includes a first spacer 81 and a second spacer 82.

Ideally, the HR non-contacting portion NS_1 includes a first spacer 81 and does not include a second spacer 82. At the HR non-contacting portion NS_1, the first spacer 81 covers a side surface of the conductor 80. An interlayer insulating film is located on a side surface of the first spacer 81.

The HR non-contacting portion NS_2 includes a first spacer 81 and a second spacer 82. At the HR non-contacting portion NS_2, the second spacer 82 covers a side surface of the conductor 80. At the HR non-contacting portion NS_2, the first spacer 81 covers a surface of the second spacer 82, excluding a portion with which the second spacer 82 and the conductor 80 are in contact. A conductor 23 or 24 is located on a side surface of the first spacer 81. In other words, the first spacer 81 includes a first portion provided between the second spacer 82 and the conductor 23 (or the conductor 24), a portion provided on a surface on one side of the second spacer 82 in the z direction, and a portion provided on a surface on the other side of the second spacer 82 in the z direction.

That is, the structure and configuration of the HR non-contacting portion NS depend on the z direction. The spacer CSP includes a portion that extends in the z direction and projects in the xy plane. The projecting portion includes a second spacer 82, and is located at the HR non-contacting portion NS_2. That is, the structure and configuration of the HR non-contacting portion NS_1 differ from those of the HR non-contacting portion NS_2.

Here, the second spacer 82 includes, for example, silicon oxide. The silicon oxide of the second spacer 82 is formed by, for example, atomic layer deposition (ALD), chemical vapor deposition (CVD), etc. The second spacer 82 offers a higher etching rate than the first spacer 81. Specifically, the second spacer 82 offers a higher etching rate for silicon oxide than the first spacer 81. At this time, examples of an etchant that can be used in silicon oxide include hydrofluoric acid (hydrofluoric solution), etc.

Ideally, the first spacer 81 is provided continuous with the HR non-contacting portion NS_1 and the HR non-contacting portion NS_2. The first spacer 81 has a shape that extends in the z direction and projects along the xy plane at the HR non-contacting portion NS_2. The first spacer 81 may have substantially the same thickness at both the HR non-contacting portion NS_1 and the HR non-contacting portion NS_2 over their entireties. However, in an actual manufacturing process, there may be a case where the first spacer 81 is not provided in an area between the HR non-contacting portion NS_1 and the HR non-contacting portion NS_2. That is, there may be a case where the first spacer 81 is not continuously provided at the HR non-contacting portion NS_1 and the HR non-contacting portion NS_2.

The second spacer 82 is located inside a portion of the HR non-contacting portion NS_2 at which the first spacer 81 projects in the xy plane. That is, the spacer CSP at the HR non-contacting portion NS_2, at which the second spacer 82 is provided, has a thickness larger than that of the HR non-contacting portion NS_1. In other words, the first spacer 81 includes a first portion provided between the second spacer 82 and the conductor 23 (or the conductor 24) and a second portion provided between the insulator 34 and the conductor 80, and a distance between the first portion and the conductor 80 in the xy plane is greater than a distance between the second portion and the conductor 80 in the xy plane.

A position of a side surface at which the spacer CSP faces the conductor 80 at the HR non-contacting portion NS_2, and a position of a side surface at which the spacer CSP faces the conductor 80 at the HR non-contacting portion NS_1 may be either aligned or not aligned in the xy plane. Herein, an example will be described in which the positions of the side surfaces are aligned. In other words, an example will be described in which a surface at which the first spacer 81 faces the conductor 80 at the HR non-contacting portion NS_1 is located on an extension of a surface at which the second spacer 82 faces the conductor 80 at the HR non-contacting portion NS_2. An example in which the positions of the side surfaces are not aligned will be described later in a modification.

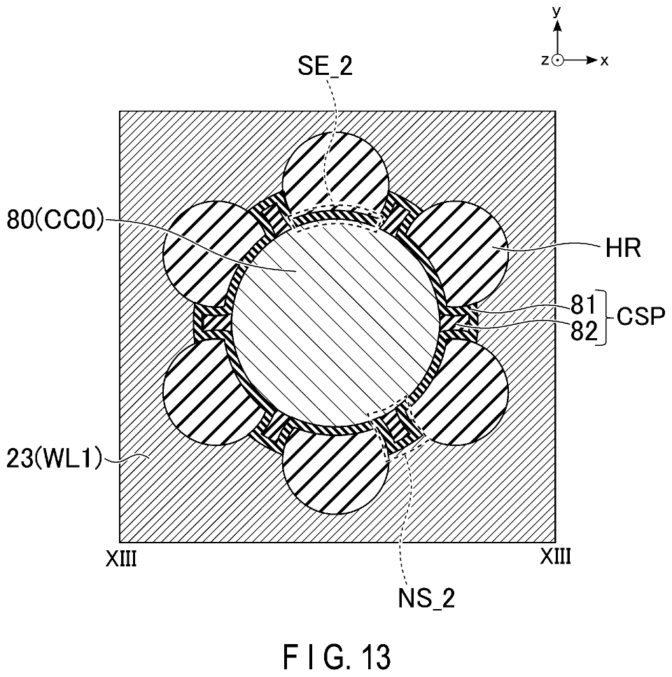

FIG. 13 shows an example of a cross-sectional structure of the periphery of the contact plug CC in the semiconductor memory device 1 according to the first embodiment. FIG. 13 shows a cross-sectional structure at coordinates different from those of FIG. 8 in the z direction, specifically, a cross section taken along line XIII-XIII in FIG. 12. That is, FIG. 13 shows a cross-sectional structure of the spacer CSP and the contact plug CC at the HR contacting portion SE_2 and the HR non-contacting portion NS_2.

As described with reference to FIG. 11, the structure and configuration of the HR contacting portion SE_2 are similar to those of the HR contacting portion SE_1. The HR contacting portion SE_2 includes a first spacer 81. The first spacer 81 covers a side surface of the conductor 80. A side surface of the first spacer 81 at the HR contacting portion SE_2 is covered with the support pillar HR. A side surface of a portion of the support pillar HR deviated from the HR contacting portion SE_2 so as to be out of contact from the first spacer 81 is covered with the conductor 23.

The HR non-contacting portion NS_2 includes the first spacer 81 and the second spacer 82. In an xy plane view, too, the first spacer 81 at the HR non-contacting portion NS_2 covers a surface of the second spacer 82, excluding a portion with which the second spacer 82 and the conductor 80 are in contact. Two adjacent support pillars HR and the conductor 23 are in contact with a side surface of the first spacer 81.

Ideally, the first spacer 81 at the HR contacting portion SE_2 and the first spacer 81 at the HR non-contacting portion NS_2 is continuously provided; however, there may be a case where they are not continuously provided. In the cross section shown in FIG. 13, the first spacer 81 has a gear-like shape. In an xy plane view, the first spacer 81 at the HR non-contacting portion NS_2 has a shape projecting in a direction away from the center of the contact plug CC, compared to the first spacer 81 at the HR contacting portion SE_2. The first spacer 81 may have substantially the same thickness at both the HR contacting portion SE_2 and the HR non-contacting portion NS_2 over their entireties. The second spacer 82 is located inside a portion at which the first spacer 81 projects in the xy plane. That is, the spacer CSP of the HR non-contacting portion NS_2, at which the second spacer 82 is provided, has a thickness larger than that of the HR contacting portion SE_2.

In other words, the structure of the spacer CSP is configured in such a manner that the first spacer 81 includes, in addition to the first portion provided between the second spacer 82 and the conductor 23 and the second portion provided between the insulator 34 and the conductor 80, a third portion provided between the support pillar HR and the conductor 80 so as to be in contact with the support pillar HR, and a portion provided between the second spacer 82 and the support pillar HR, and so that a distance between the first portion and the conductor 80 in the xy plane is greater than a distance between the third portion and the conductor 80 in the xy plane.

In the foregoing, the hook-up area HA1 has been described, and in particular, the spacer CSP and the contact plugs CC0 to CC8 have been described, with reference to FIGS. 7 to 13. The hook-up area HA2 and other spacers CSP and contact plugs CC are respectively similar to the hook-up area HA1, the spacer CSP, and the contact plugs CC0 to CC8 described with reference to FIGS. 7 to 13. That is, the hook-up area HA2 has a plane layout obtained by inverting a plane layout of the hook-up area HA1 along the y-axis. A contact plug CC other than the contact plugs CC0 to CC8 is, at its lower surface, for example, in contact with a conductor 23 different from a conductor 23 that another contact plug CC is in contact with.

### <1-2> Method of Manufacturing Semiconductor Memory Device 1

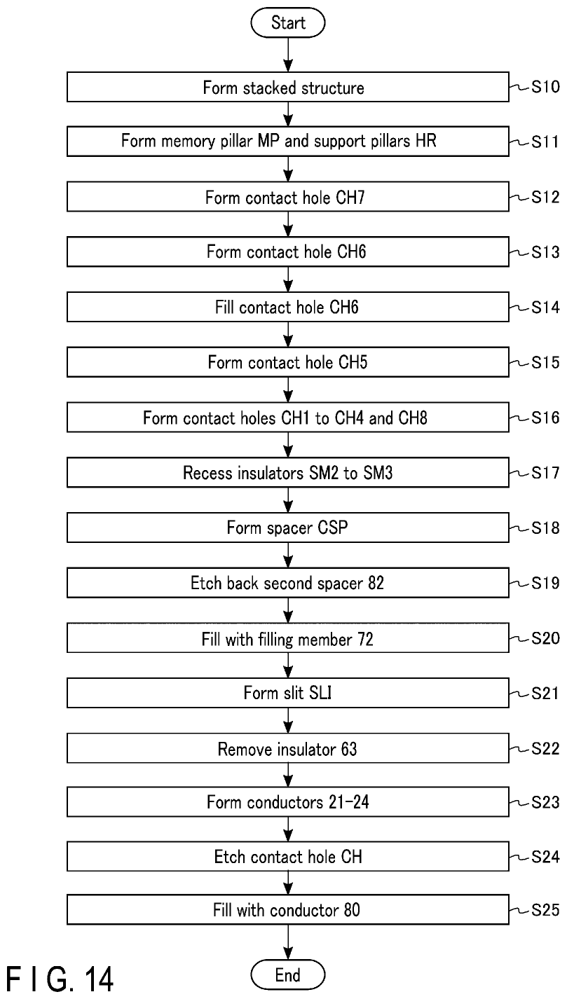

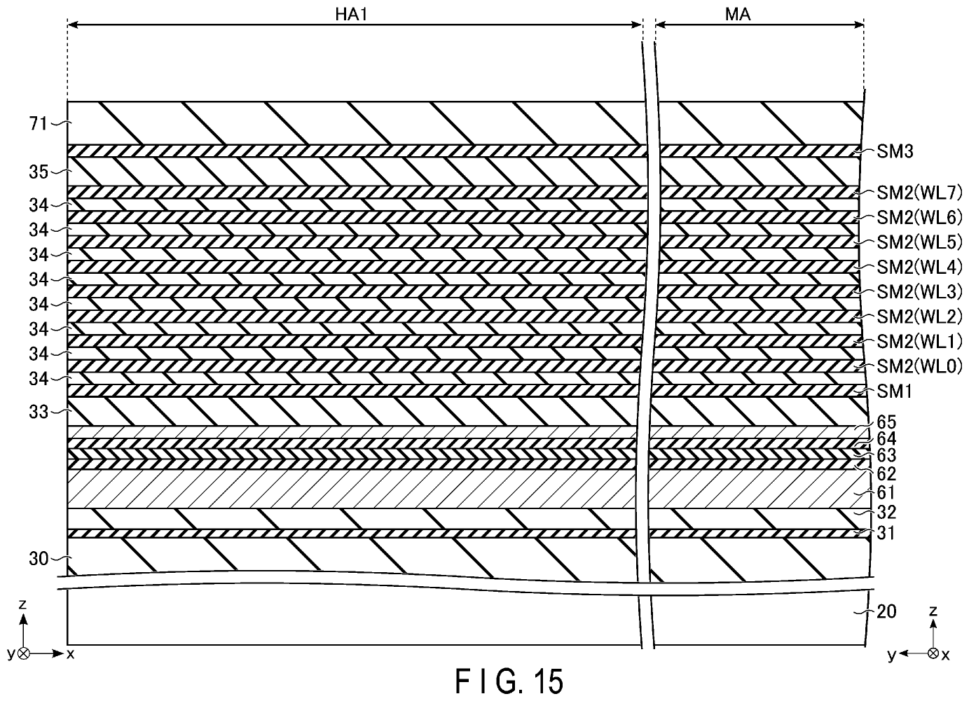

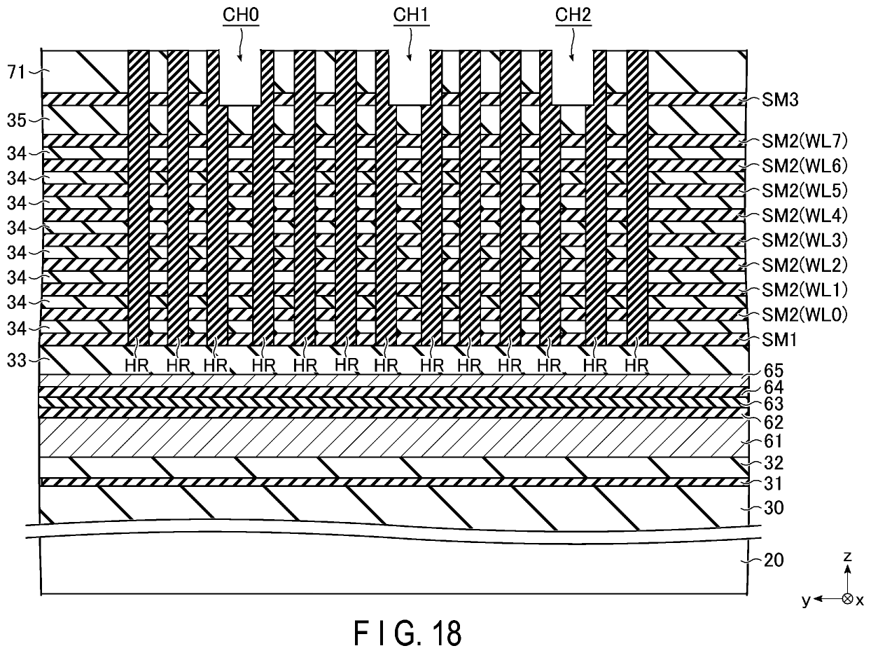

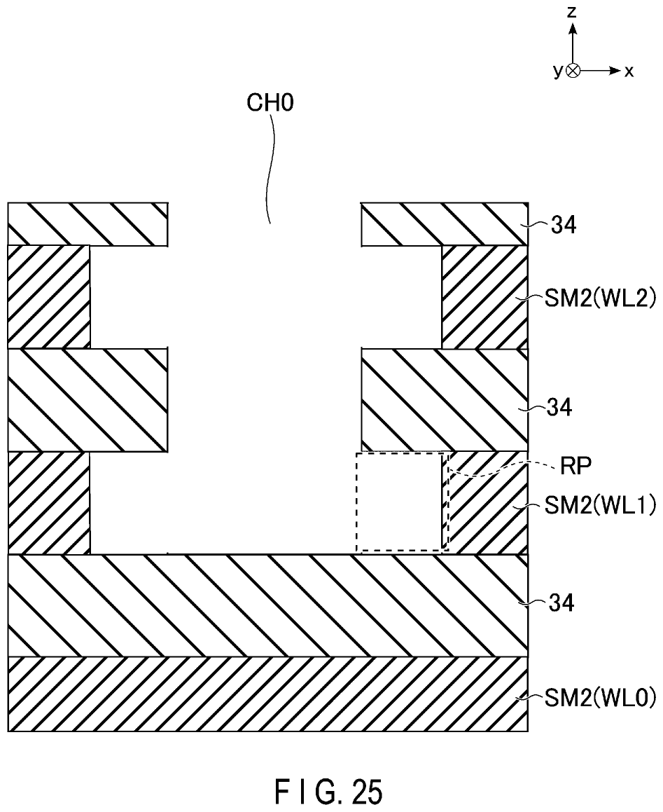

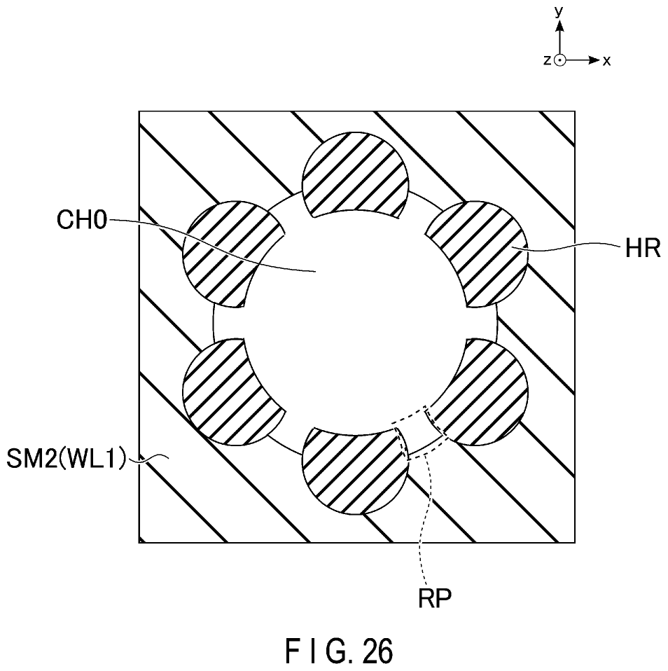

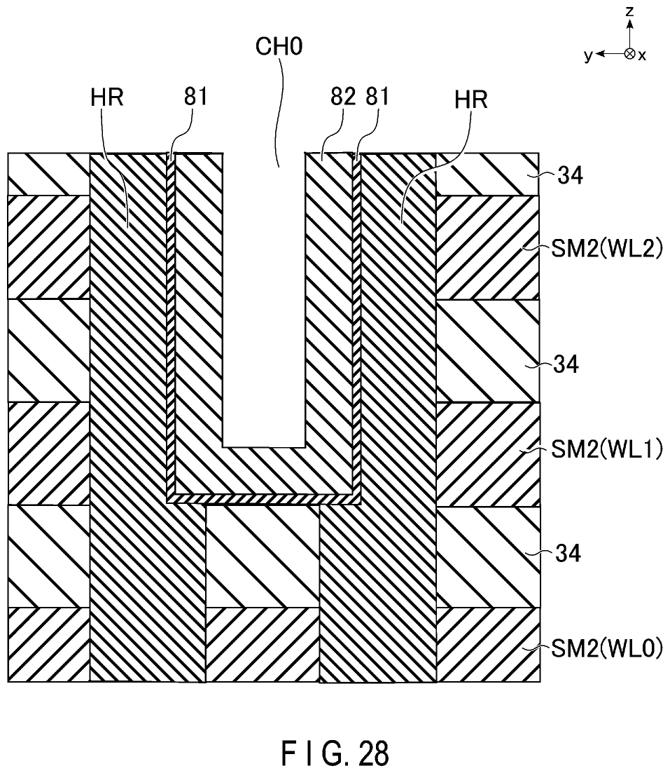

FIG. 14 is a flowchart showing an example of a manufacturing method of the semiconductor memory device 1 according to the first embodiment. Each of FIGS. 15 to 40 shows an example of a cross-sectional structure at a step in a manufacturing process of the semiconductor memory device 1 according to the first embodiment. FIGS. 15 to 17, 19 to 21, 23, and 33 to 35 show cross sections of an area that is the same as the area of the cross section shown in FIG. 9. FIGS. 18, 22, 24, and 36 show cross sections of an area that is the same as the area of the cross section shown in FIG. 10. FIGS. 25, 27, 29, 31, 37, and 39 show cross sections of an area that is the same as the area of the cross section shown in FIG. 12. FIG. 26 shows a cross section of an area that is the same as the area of the cross section shown in FIG. 13. FIGS. 28, 30, 32, 38, and 40 show a cross section of an area that is the same as the area of the cross section shown in FIG. 11.

Hereinafter, an example of a manufacturing process related to formation of a contact plug CC and a spacer CSP in the semiconductor memory device 1 according to the first embodiment will be described with reference to FIG. 14. As shown in FIG. 14, in the manufacturing method of the semiconductor memory device 1 according to the first embodiment, steps S10 to S25, for example, are sequentially carried out.

In processing at step S10, a stacked structure is formed, as shown in FIG. 15. Specifically, after a circuit (not illustrated) is formed on a substrate 20, insulators 30 to 32, a conductor 61, insulators 62, 63, and 64, and a conductor 65 are deposited in this order on an upper surface of the substrate 20. A group of the conductor 61, the insulators 62, 63, and 64, and the conductor 65 occupies an area where a conductor 21 is to be formed.

On an upper surface of the conductor 65, an insulator 33 is formed.

On an upper surface of the insulator 33, an insulator SM1 is formed. The insulator SM1 is located in an area where a conductor 22 is to be formed. The insulator SM1 includes, for example, silicon nitride.

On an upper surface of the insulator SM1, a plurality of insulators 34 and a plurality of insulators SM2 are alternately deposited one by one. The insulator SM2 is located in an area where a conductor 23 is to be formed. The insulator SM2 includes, for example, silicon nitride.

On an upper surface of the uppermost insulator SM2, an insulator 35, an insulator SM3, and an insulator 71 are deposited in this order. The insulator SM3 is located in an area where a conductor 24 is to be formed. The insulator 71 configures a part of the insulator 36. The insulator SM3 includes, for example, silicon nitride.

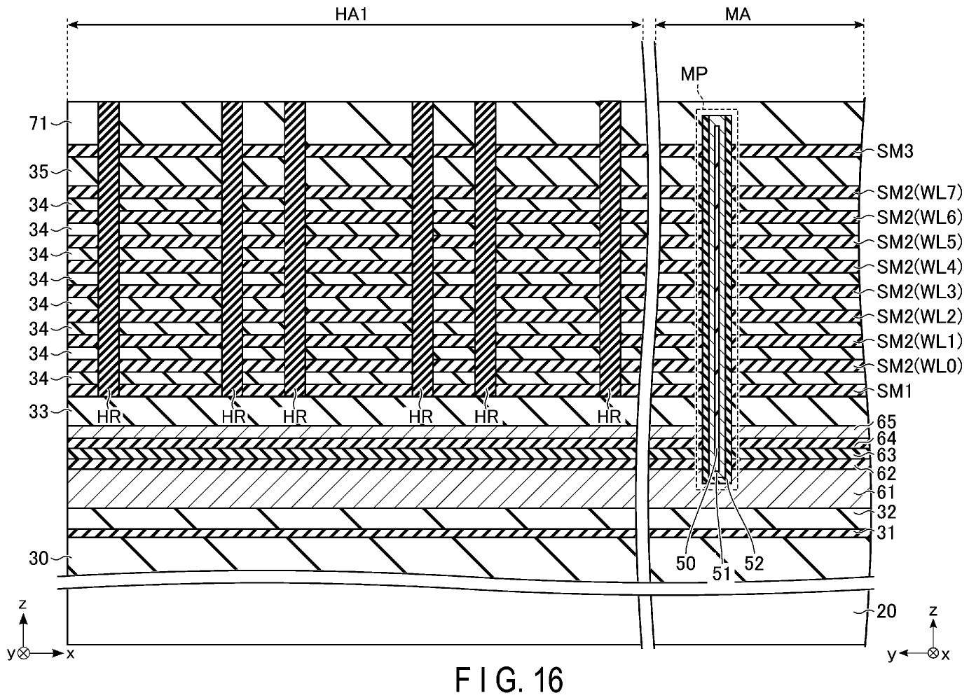

In processing at step S11, a memory pillar MP and support pillars HR are formed, as shown in FIG. 16. It is to be noted that, at this stage, a layer stack 52 of the memory pillar MP does not include an opening. Details will be described below. That is, a memory hole is formed by photolithography and anisotropic etching. The memory hole is located in an area where a memory pillar MP is to be formed. The memory hole penetrates the insulators 71, SM3, 35, SM2, 34, SM1, and 33, the conductor 65, and the insulators 64, 63, and 62. A bottom of the memory hole is located in the conductor 61. On a surface of the memory hole, a layer stack 52, that is, a tunnel insulator 53, a charge storage film 54, and a block insulator 55, is formed. On a surface of the layer stack 52, a semiconductor 51 is formed. On a surface of the semiconductor 51, a core 50 is formed, and thereby a center of the memory hole is filled with the core 50. Thereafter, an upper portion of the core 50 is removed, and the semiconductor 51 is formed in the removed portion. In this manner, the memory pillar MP is formed, and then an insulator is formed on an upper surface of the memory pillar MP. Such an insulator is depicted as a part of the insulator 71 in FIG. 16.

A plurality of support pillars HR are formed. Each of the support pillars HR penetrates the insulators 71, SM3, 35, SM2, 34, and SM1. Each of the support pillars HR extends from an upper surface of the insulator 71 to an upper surface of the insulator 33.

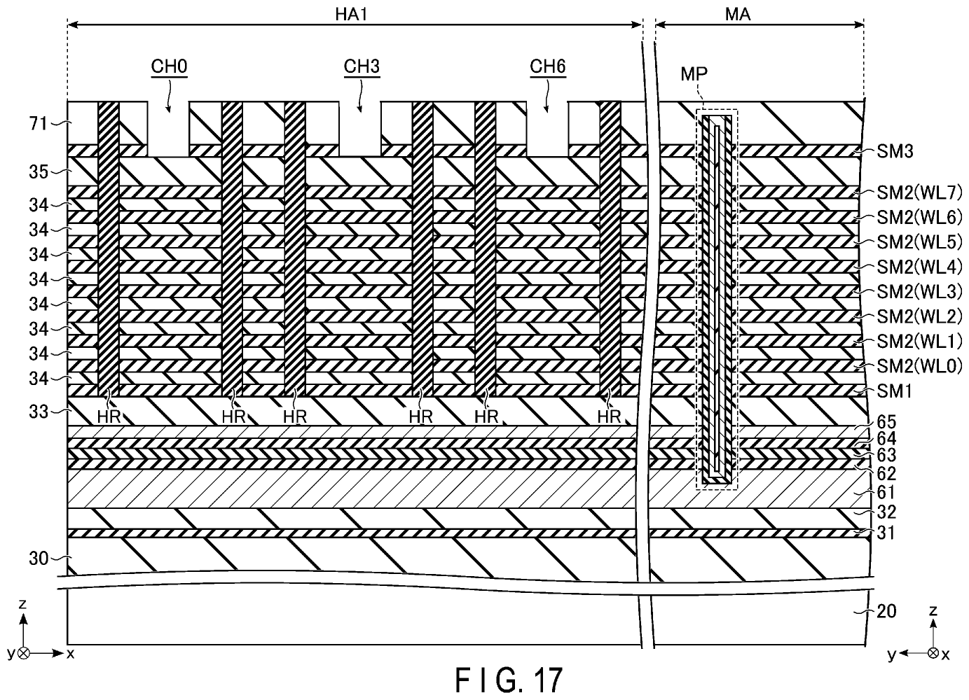

In processing at step S12, parts of contact holes CH are formed, as shown in FIGS. 17 and 18. The contact holes CH are located in an area where contact plugs CC are to be formed. A concrete formation method will be described below.

A mask is formed on an upper surface of the insulator 71 by photolithography. The mask includes openings above areas where contact plugs CC0 to CC8 are to be formed. Anisotropic etching is performed via the mask, and thereby contact holes CH0 to CH8 are formed. The contact holes CH0 to CH8 penetrate the insulators 71 and SM3, and reach an upper surface of the insulator 35. Thereby, a bottom of the contact hole CH7 (not illustrated), for example, reaches its objective depth.

As described above, bottoms of the contact plugs CC are located at different heights according to the position of the conductor 23 or 22 that each contact plug CC is in contact with. Accordingly, bottoms of the contact holes CH are also located at different depths at a stage before being filled with the conductor 80. For this objective, a bottom of a contact hole CH located at a deeper position (a position closer to the substrate 20) is further etched at step S12 and thereafter. Through step S12 and thereafter, each contact hole CH is etched so as to have an intended (target) depth unique to the contact hole CH. A contact hole CH to be formed with a greater intended depth is repeatedly etched. On the other hand, a contact hole CH that has reached the intended depth is filled with a filling member NG, to be described later, during further etching of another contact hole CH.

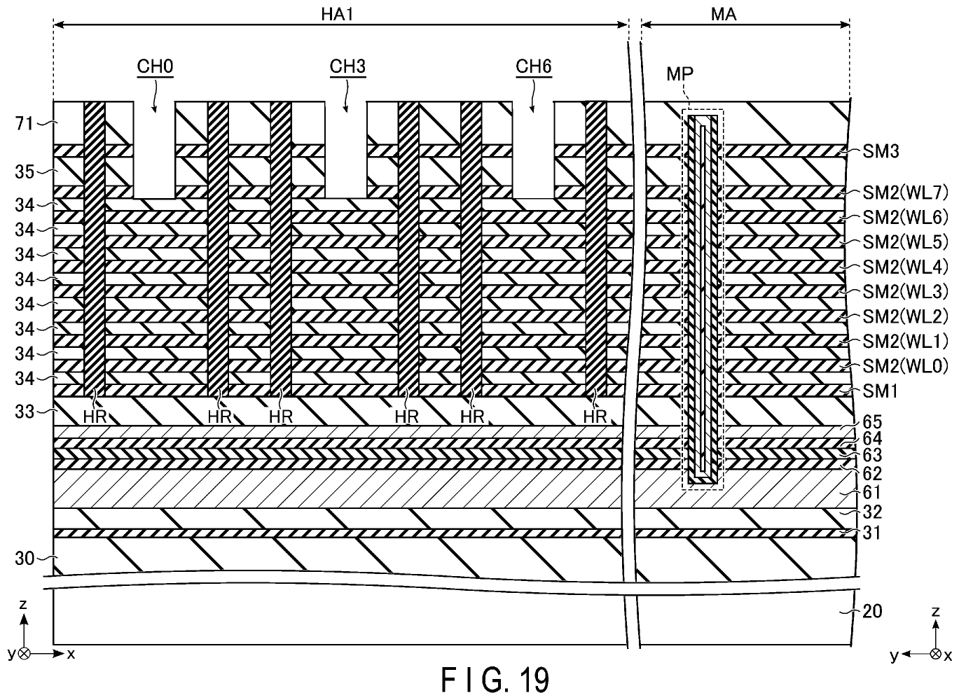

In processing at step S13, bottoms of the contact holes CH0 to CH6 and CH8 are etched, as shown in FIG. 19. The bottoms of the contact holes CH0 to CH6 and CH8 have objective depths that are greater than the bottom of the contact hole CH7. Thus, the bottoms of the contact holes CH0 to CH6 and CH8 reach positions at greater depths through the etching. Details of the etching will be described later with reference to step S15. As a result, the contact holes CH0 to CH6 and CH8 reach an upper surface of an insulator 34 on an upper surface of the insulator SM2 that is located in an area where a conductor 23 that is to function as the word line WL6 is to be formed. Thereby, the bottom of the contact hole CH6, for example, reaches its objective depth. At this time, a contact hole CH that has already reached its objective depth, such as the contact hole CH7, is filled with a filling member NG (not illustrated).

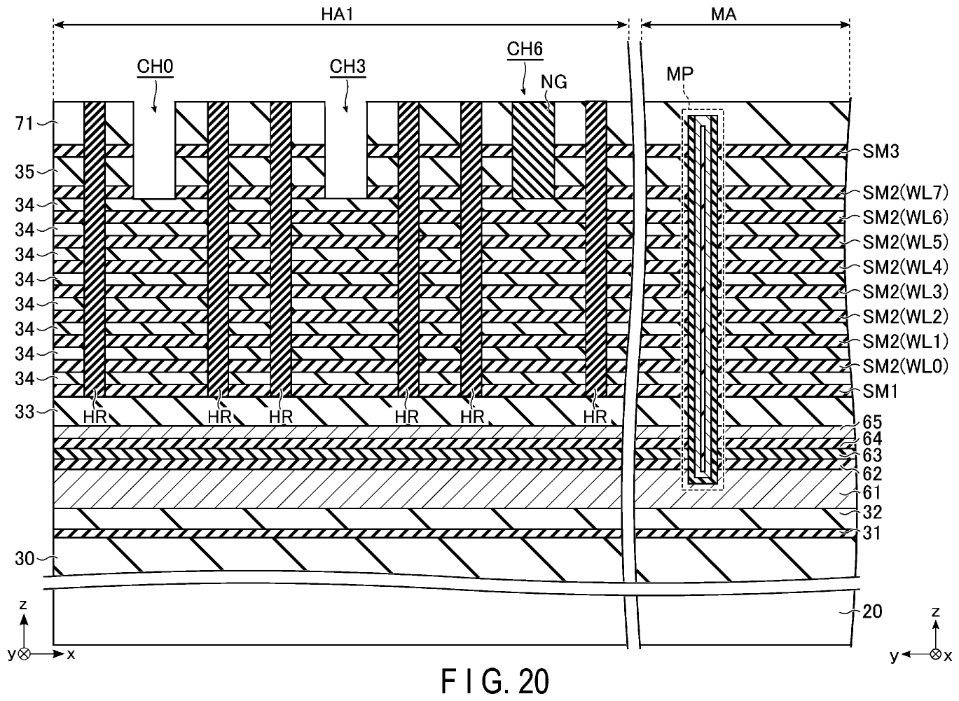

In processing at step S14, the contact hole CH6 is filled with a filling member NG, as shown in FIG. 20. The filling member NG is, for example, a negative resist. Specifically, a negative resist is applied onto an upper surface of a structure obtained by performing the steps so far. Subsequently, on an upper surface of the above-described structure, a mask that includes an opening above an area that is to be filled with a filling member NG, namely, the contact hole CH6, is formed. The negative resist is exposed to light through the opening of the mask. As a result, a portion below the opening of the mask in the negative resist, that is, a portion in the contact hole CH6, is cured. After that, a portion of the negative resist that has not been cured is removed.

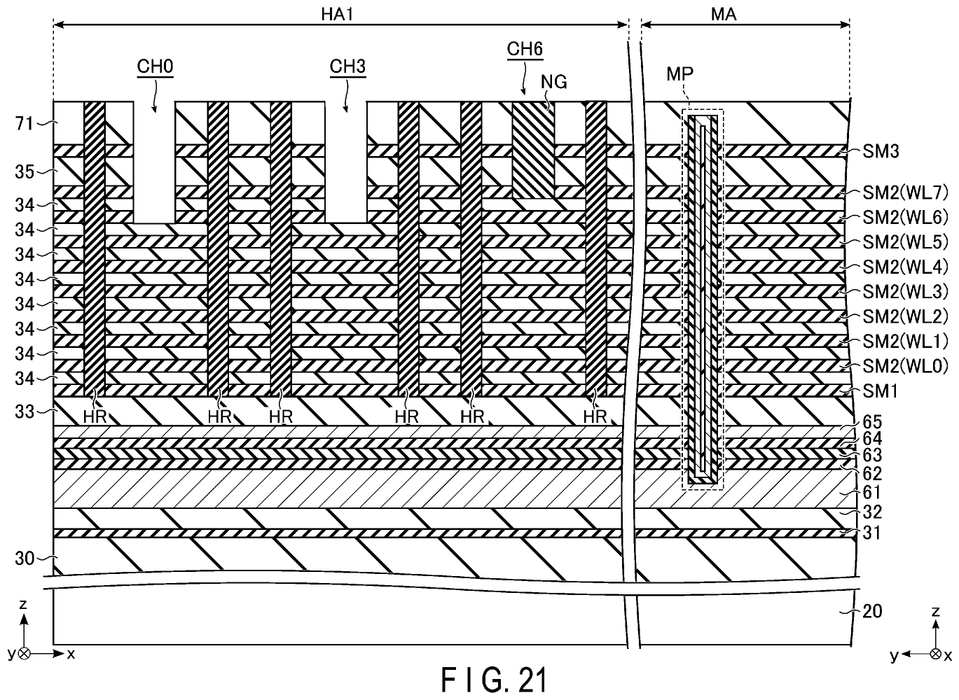

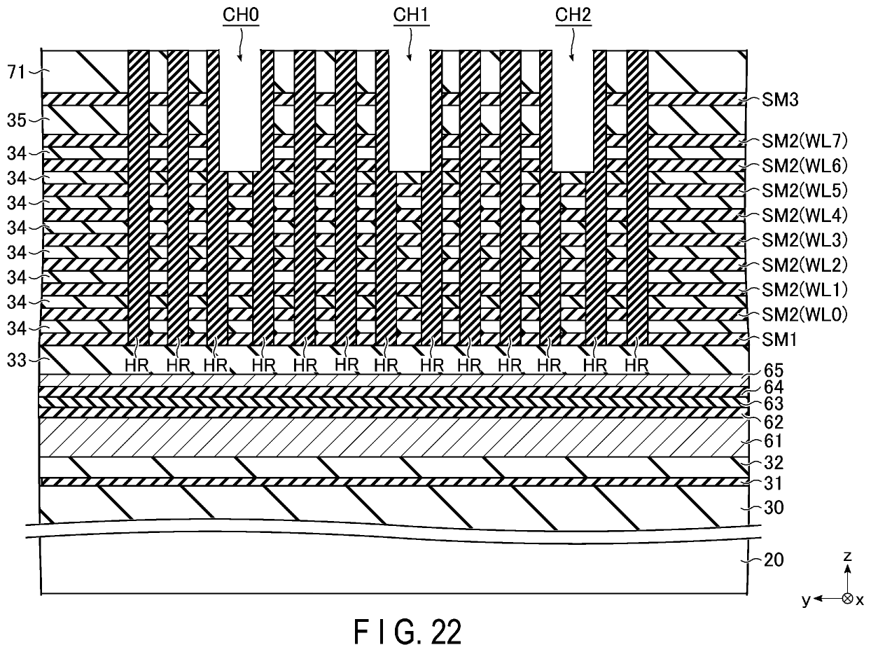

In processing at step S15, bottoms of the contact holes CH0 to CH5 and CH8 are etched, as shown in FIGS. 21 and 22. Specifically, anisotropic etching is performed on the structure obtained by performing the steps so far. Etching is performed under the condition that a high selectivity is ensured between the insulators SM2 and 34 and the filling member NG. As a result, bottoms of contact holes CH that are not filled with the filling member NG, namely, the contact holes CH0 to CH5 and CH8, are etched. Through the etching, the bottoms of the contact holes CH0 to CH5 and CH8 reach an upper surface of an insulator 34 on an upper surface of an insulator SM2 that is located in an area where a conductor 23 that is to function as the word line WL5 is to be formed. Thereby, the bottom of the contact hole CH5, for example, reaches its objective depth.

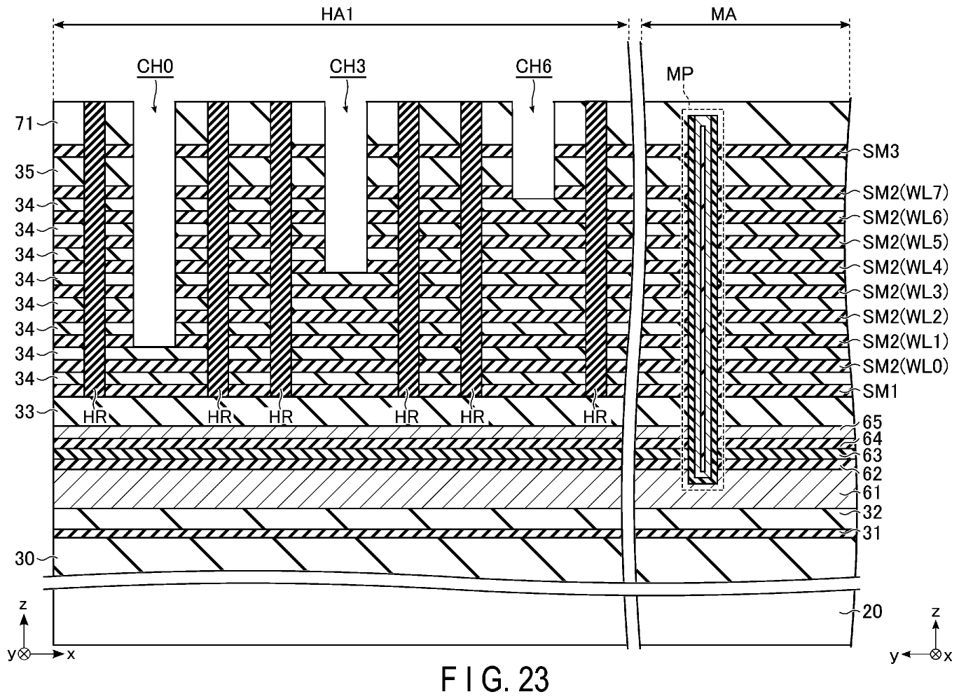

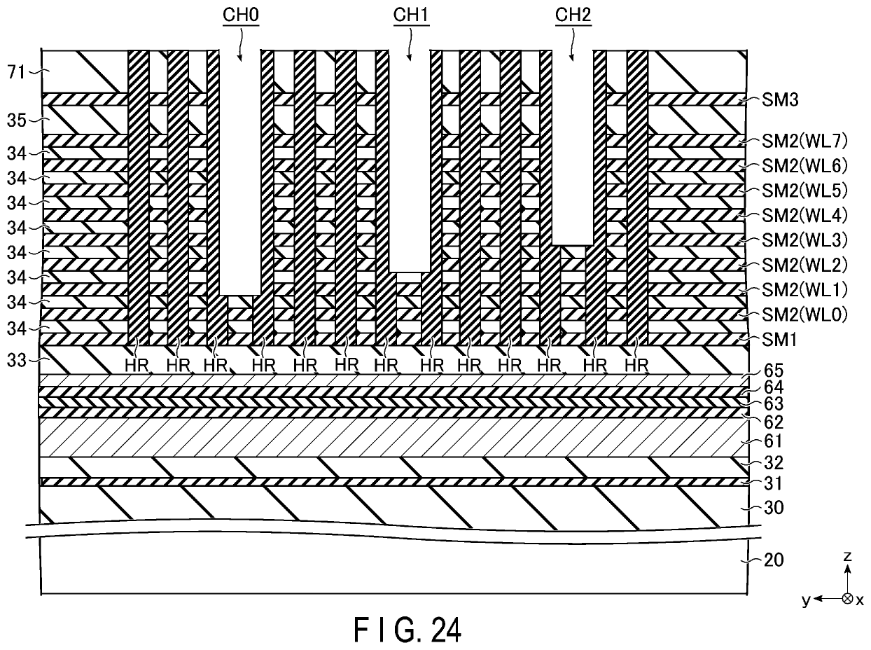

In processing at step S16, processing similar to the processing at steps S14 and S15 is repeated, and thereby the bottoms of the contact holes CH0 to CH4 and CH8 are etched, as shown in FIGS. 23 and 24. As a result, the bottoms of the contact holes CH0 to CH4 respectively reach upper surfaces of insulators 34 on upper surfaces of insulators SM2 that are located in areas where conductors 23 that are to function as the word lines WL0 to WL4 are to be formed. The bottom of the contact hole CH8 reaches an upper surface of an insulator 34 on an upper surface of an insulator SM1 that is located in an area where a conductor 22 that functions as the select gate line SGSL is to be formed. Through this process, contact holes CH that have reached their objective depths are filled with a filling member NG.

After that, the filling member NG is removed from each of the contact holes CH. The removing can be performed by either wet etching or ashing.

In processing at step S17, the insulators SM2 to SM3 are partially recessed, as shown in FIGS. 25 and 26. Specifically, wet etching is carried out via the contact holes CH, and the insulators SM2 to SM3 exposed to side surfaces of the contact holes CH are partially removed. Thereby, the side surfaces of the contact holes CH are processed into a shape from which the insulators SM2 to SM3 are partially removed in an area where an HR non-contacting portion NS_2 is to be formed. The space generated by partially removing the insulators SM2 to SM3 in this process may be hereinafter referred to as a “space RP”. The space RP is formed in, for example, the area where the HR non-contacting portion NS_2 is to be formed.

Since the insulators SM2 to SM3 are not exposed to the side surfaces of the contact holes CH in areas where the HR non-contacting portion NS_1, the HR contacting portion SE_1, and the HR contacting portion SE_2 are to be formed (which are not illustrated), wet etching is not carried out in these areas. Since the space RP has been formed, the contact hole CH has a greater diameter in the area where the HR non-contacting portion NS_2 is to be formed, compared to the other areas.

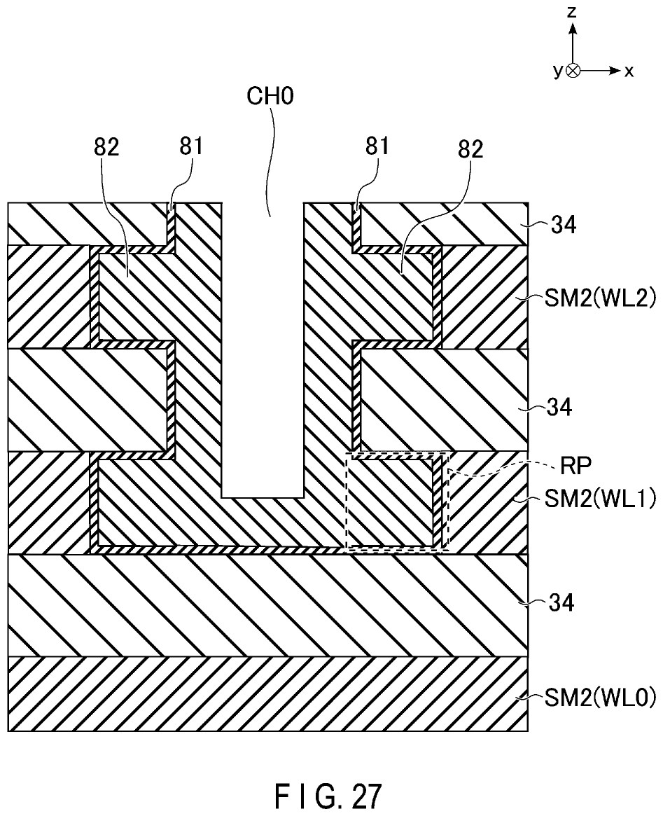

In processing at step S18, a spacer CSP is formed, as shown in FIGS. 27 and 28. Specifically, a first spacer 81 is formed on surfaces of the contact hole CH, including a bottom surface and surfaces exposed to the space RP. Subsequently, a second spacer 82 is formed on surfaces of the first spacer 81. The space RP formed in the area where the HR non-contacting portion NS_2 is to be formed is occluded by the second spacer 82. That is, the first spacer 81 and the second spacer 82, which are to be spacers CSP at the HR non-contacting portion NS_2, are formed on the side surfaces of the contact hole CH.

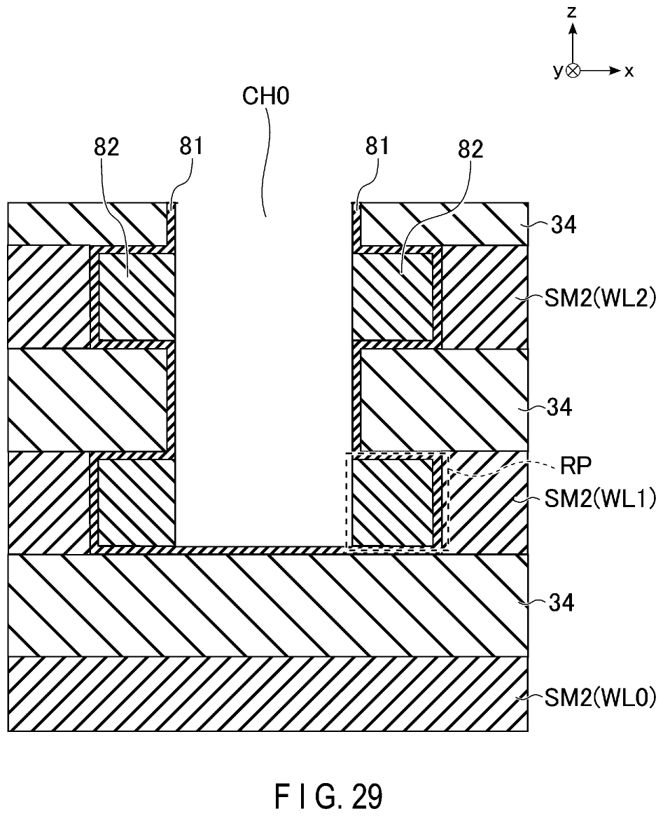

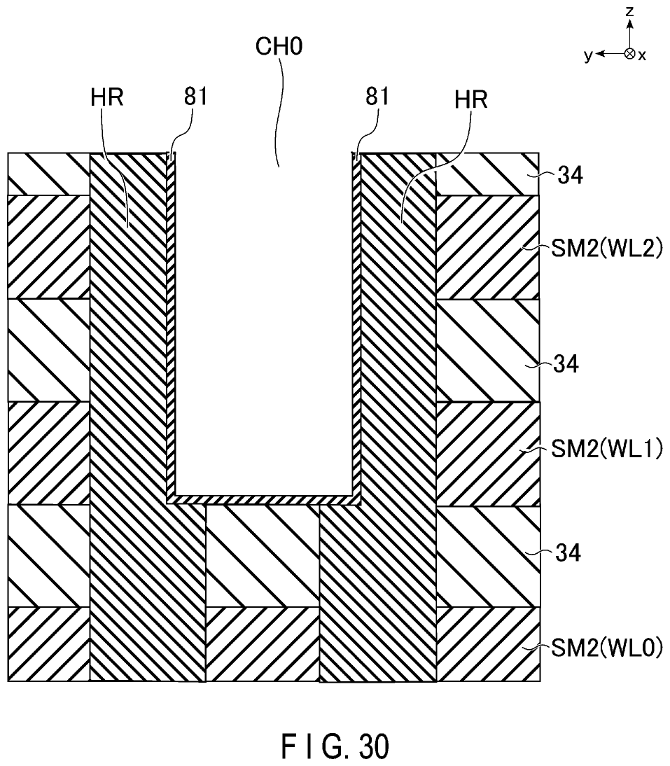

In processing at step S19, the second spacer 82 is partially etched back, as shown in FIGS. 29 and 30. Specifically, wet etching is carried out via the contact hole CH, and a part of the second spacer 82 that is exposed to the side surfaces of the contact hole CH is removed.

Thereby, the second spacer 82 is removed, excluding the area where the HR non-contacting portion NS_2 is to be formed in the contact hole CH, and thereby the first spacer 81 is exposed. That is, a structure of the spacer CSP at the HR non-contacting portion NS_1, the HR contacting portion SE_1, and the HR contacting portion SE_2 is formed on the side surfaces of the contact hole CH. Also, the first spacer 81 is exposed to the bottom surface of the contact hole CH.

The first spacer 81 offers a lower etching rate than the second spacer 82. Accordingly, even if the second spacer 82 is removed by wet etching, the first spacer 81 remains at the HR non-contacting portion NS_1, the HR contacting portion SE_1, and the HR contacting portion SE_2. Similarly, at the bottom surface of the contact hole CH, even if the second spacer 82 is removed by wet etching, the first spacer 81 remains as a film.

Through the removing of the second spacer 82 in the contact hole CH, allowing the second spacer 82 in the space RP to remain, the structure of the spacer CSP at the HR non-contacting portion NS_2 is formed. That is, the second spacer 82 remains in the area where the HR non-contacting portion NS_2 is to be formed. At this time, the second spacer 82 ideally remains only at the HR non-contacting portion NS_2. That is, the second spacer 82 is not provided between the HR contacting portion SE_2 and the contact plug CC ideally. In other words, the second spacer 82 ideally does not remain on the side surfaces of the first spacer 81 at a position that is opposite to the support pillar HR. In addition, the second spacer 82 does not remain in a layer including the interlayer insulating film.

It suffices that the second spacer 82 at the HR non-contacting portion NS_2 may be formed with a thickness that ensures insulating properties between the contact plug CC and the word lines WL in the xy plane. That is, the second spacer 82 formed in the space RP may be etched by letting a minimum amount that does not cause a problem in a withstanding pressure between the contact plug CC and the word line WL remain. A position of a side surface at which the spacer CSP faces the contact hole CH at the HR non-contacting portion NS_2 and a position of a side surface at which the spacer CSP faces the contact hole CH at the HR non-contacting portion NS_1 may be either aligned or not aligned in the xy plane. Herein, an example will be described in which the positions of the side surfaces are aligned.

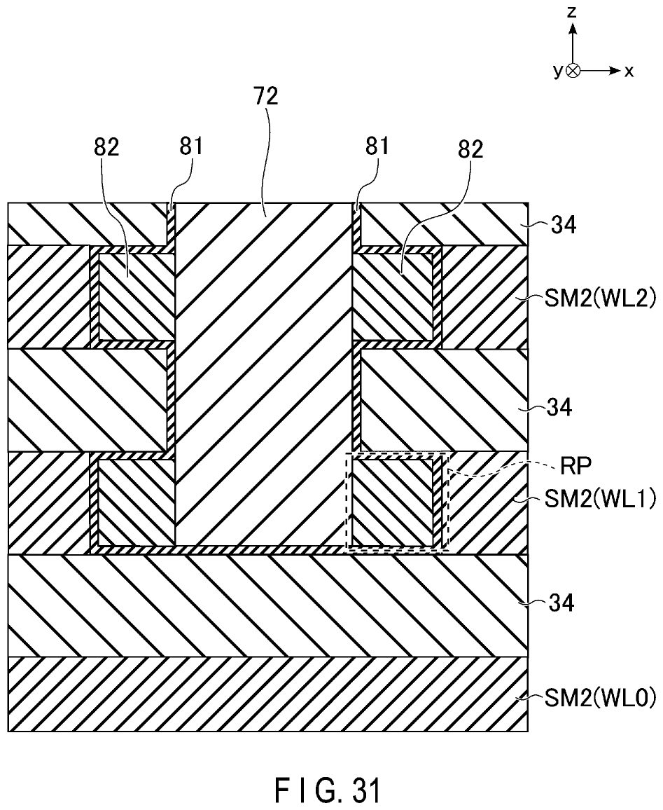

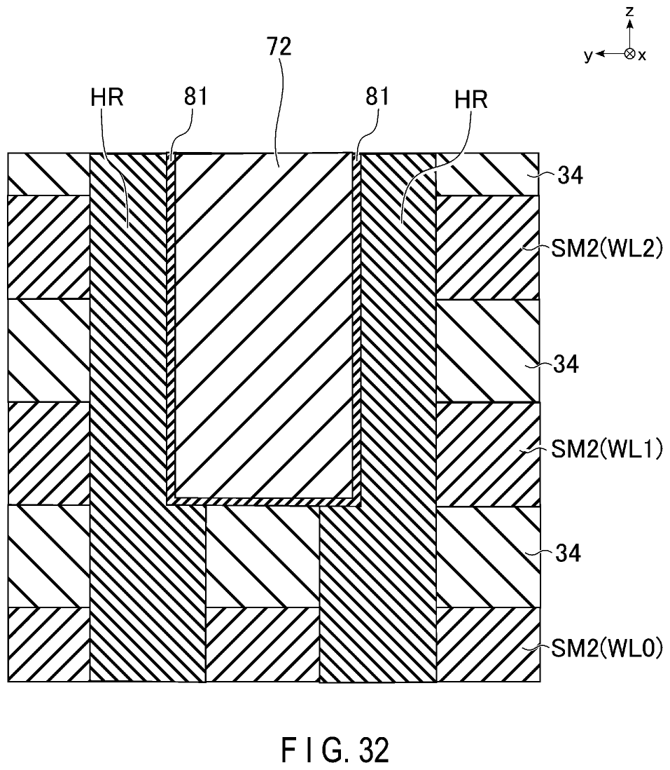

In processing at step S20, a contact hole CH is filled with a filling member 72, as shown in FIGS. 31 and 32. The filling member 72 is, for example, amorphous silicon or carbon.

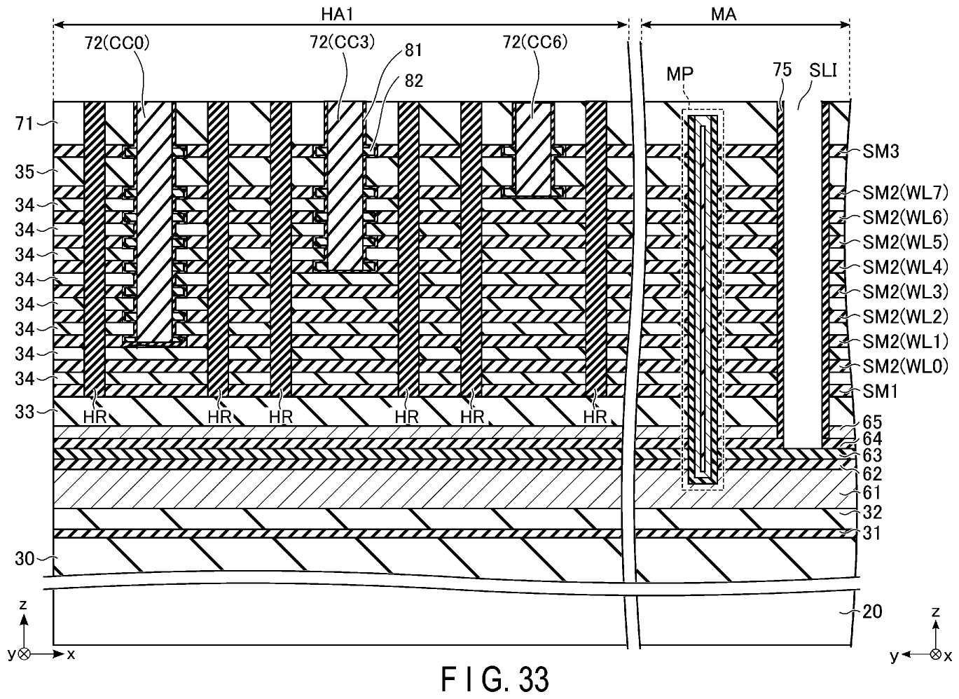

In processing at step S21, a slit SLI is formed by photolithography and anisotropic etching, as shown in FIG. 33. The slit SLI is located in an area where the member SLT is to be formed. A bottom of the slit SLI reaches an upper surface of the insulator 64. An insulator 75 is formed on surfaces of the slit SLI. A portion of the insulator 75 at the bottom of the slit SLI and a portion of the insulator 64 below the slit SLI are removed. As a result, the insulator 63 is exposed to the bottom of the slit SLI.

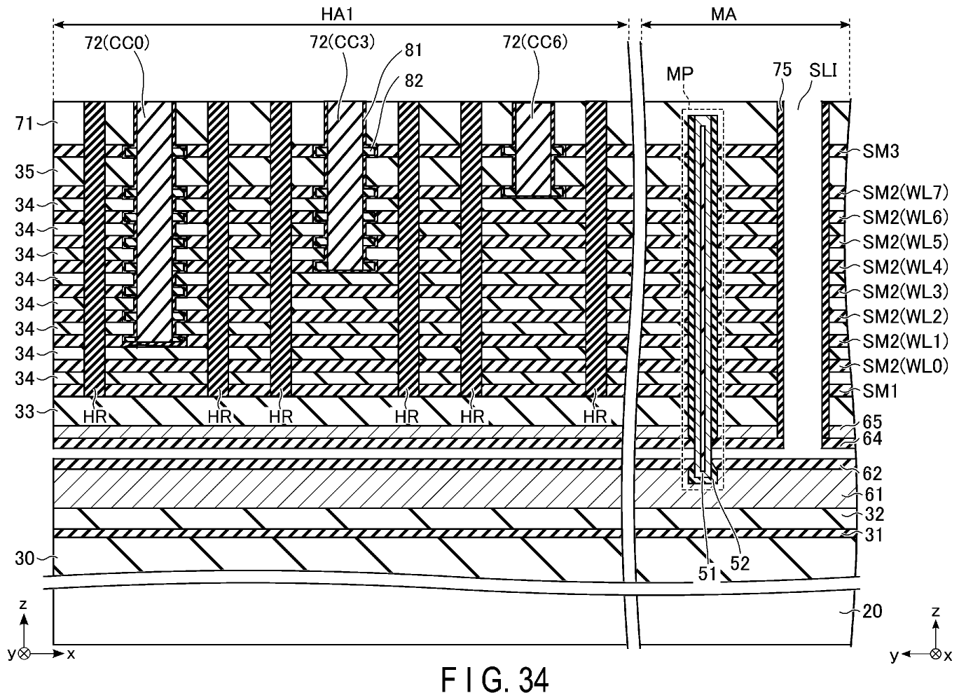

In processing at step S22, the bottom of the slit SLI, that is, the insulator 63, is subjected to a chemical by wet etching, as shown in FIG. 34. The chemical removes the insulator 63. At this time, a portion of the layer stack 52 of the memory pillar MP that is located in a layer of the insulator 63 is removed, and the semiconductor 51 is exposed to the removed portion.

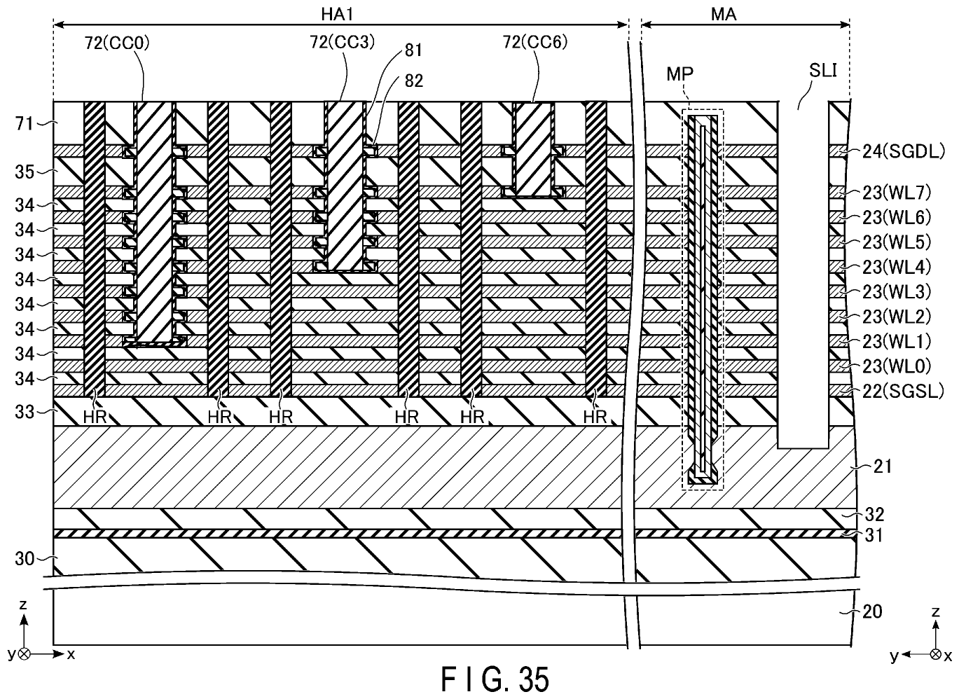

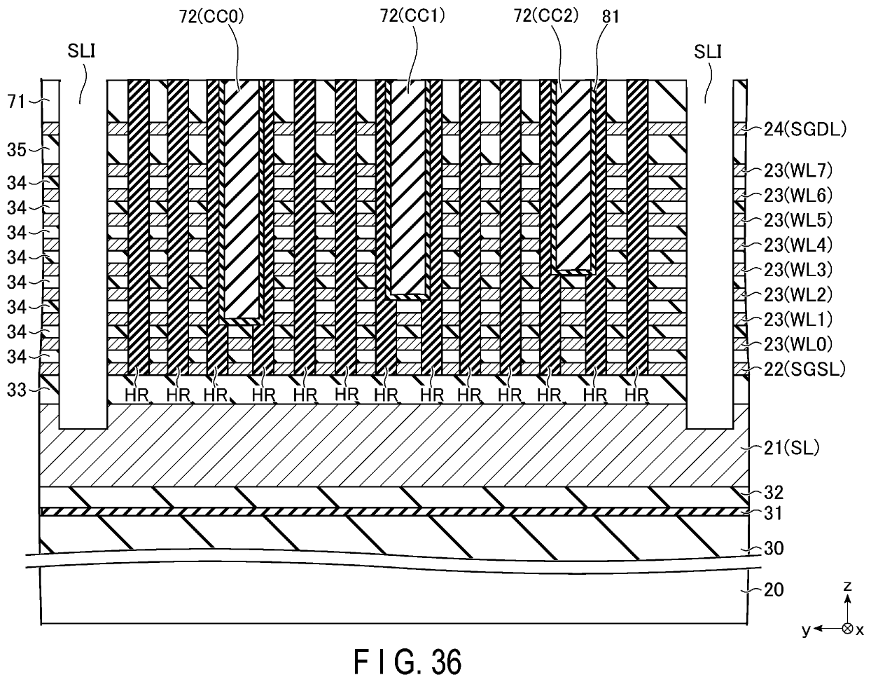

In processing at step S23, a chemical advances from a space where the insulator 63 had been located at the bottom of the slit SLI through wet etching, as shown in FIGS. 35 and 36. The chemical removes the insulators 62 and 64. A space where the insulators 62 and 64 had been located is filled with a conductor, and thereby a conductor 21 is formed.

Subsequently, the insulator 75 is removed. Through the removing of the insulator 75, the insulators SM1 to SM3 are exposed to an inside of the slit SLI. The exposed portions of the insulators SM1 to SM3 are subjected to a chemical by wet etching. With an advancement of the chemical, the insulators SM1 to SM3 are removed, and a space is formed in an area where the insulators SM1 to SM3 had been located. This weakens the structure of the semiconductor memory device 1 being manufactured, and in particular, destabilizes a portion of the structure with a high aspect ratio. However, with a large number of support pillars HR provided, the shape of the structure is suppressed from collapsing.

By filling the area where the insulators SM1 to SM3 had been located with a metal material such as tungsten or molybdenum via the slit SLI, conductors 22 to 24 are formed.

A high dielectric constant insulator that functions as a block insulating film may be formed in the periphery of the conductors 22 to 24. A manufacturing method in such a case will be described later in a modification.

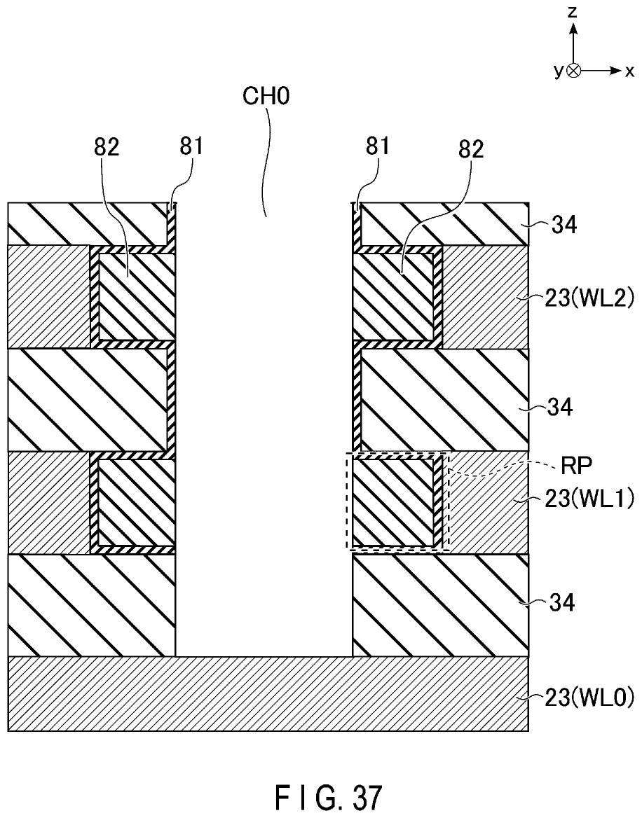

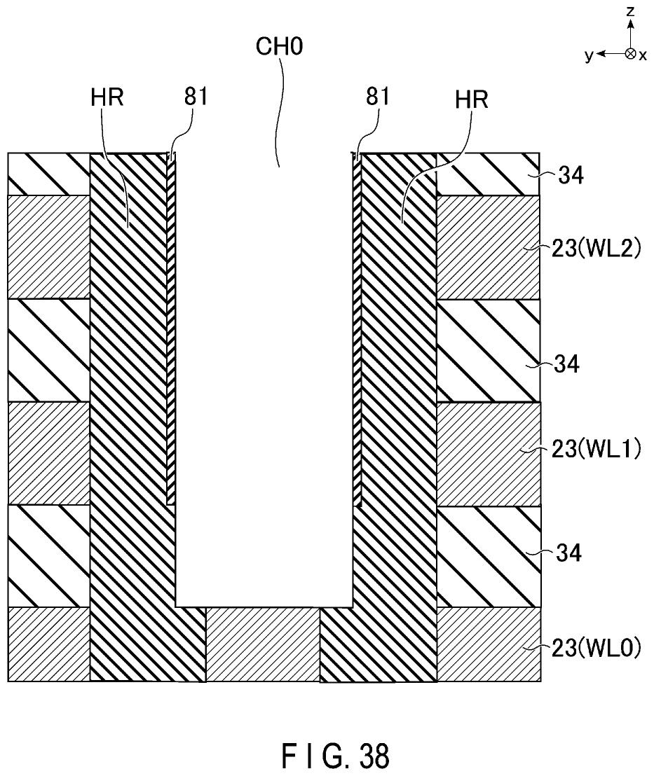

In processing at step S24, anisotropic etching is performed on a bottom surface of the contact hole CH, as shown in FIGS. 37 and 38. Specifically, the filling member 72 is removed, and a contact hole CH is formed. Etching is carried out via the contact hole CH, and a portion of the first spacer 81 that is exposed to the bottom surface of the contact hole CH is removed. Thereby, a portion of the first spacer 81 at the bottom of the contact hole CH is removed. Moreover, a portion of the insulator 34 that has been exposed by the removing of the first spacer 81 at the bottom of the contact hole CH is removed. Thereby, the conductor 23 that had been in contact with a lower surface of the removed portion of the insulator 34 is exposed to the bottom of the contact hole CH.

The etching is performed by, for example, reactive ion etching (RIE). First, etching is carried out to an extent at which the first spacer 81 and the insulator 34 can be removed, and over-etching is performed to fully perform etching of the entire surface, even if the film thickness is not unique. The amount of over-etching depends on the thickness of the target to be removed.

During this etching, support pillars HR that overlap the contact holes CH are also partially removed. Upper surfaces of the support pillars HR that have been partially removed are flush with, for example, an exposed portion of the upper surface of the conductor 23.

Also, a side surface of the slit SLI is covered with the spacer SP. Thereafter, the slit SLI is filled with a conductor, and thereby a member SLT is formed.

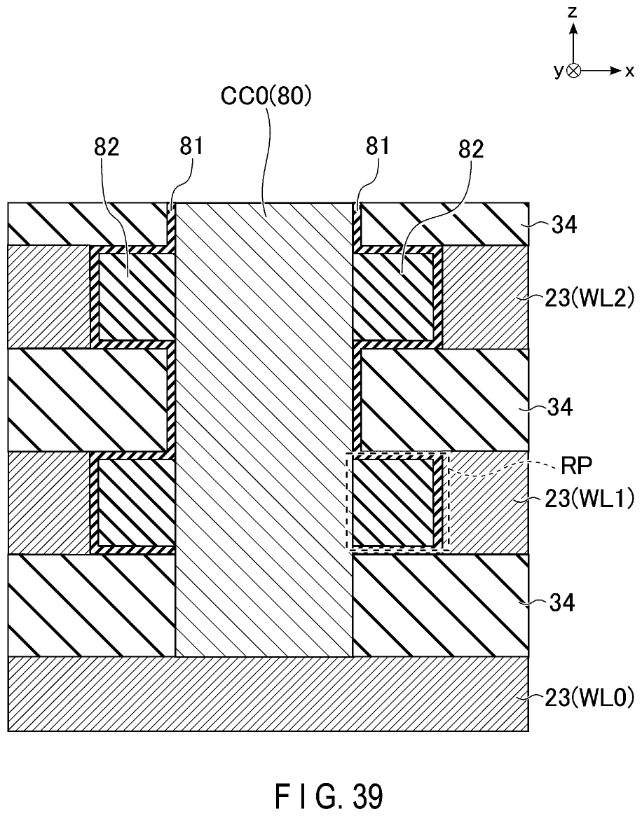

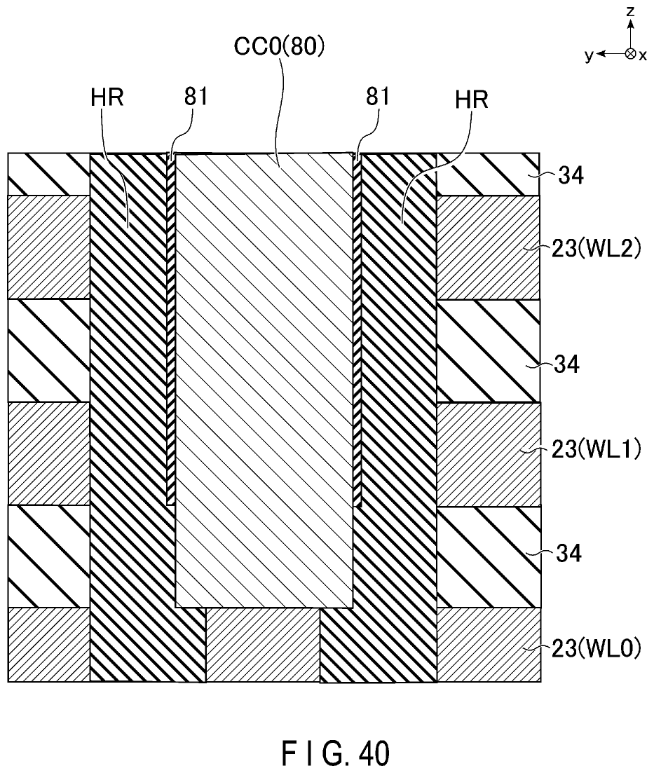

In processing at step S25, the contact hole CH is filled with a conductor 80, as shown in FIGS. 39 and 40. Thereby, a contact plug CC is formed.

With the formation of the member SHE, the conductor 83, the contact CV, the conductor 25, and the remaining portion of the insulator 36, etc., the structure shown in FIGS. 9 and 10 is completed.

### <1-3> Advantages (Effects) of First Embodiment

With the structure and configuration of the spacer CSP including the first spacer 81 and the second spacer 82, it is possible in the semiconductor memory device 1 according to the first embodiment described above to improve the yield of the semiconductor memory device 1. Detailed effects of the spacer CSP will be described below.

First, with the spacer CSP of the semiconductor memory device 1 according to the first embodiment, it is possible to suppress a current leak between the contact plug CC and the word line WL.

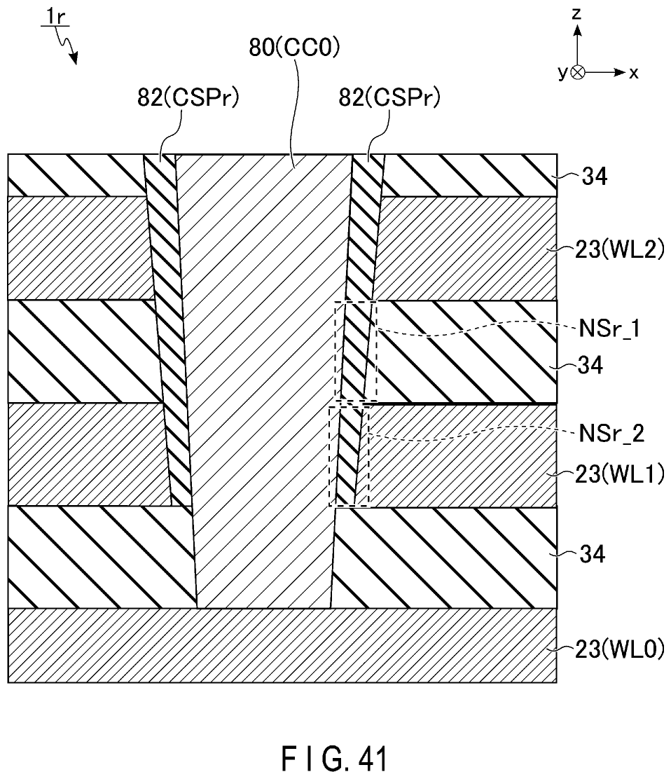

Here, a semiconductor memory device 1 according to a comparative example of the first embodiment will be described with reference to FIG. 41. The semiconductor memory device 1 and the spacer CSP according to the comparative example of the first embodiment may be respectively referred to as a “semiconductor memory device 1r” and a “spacer CSPr”. Also, the HR non-contacting portion NS, the HR non-contacting portion NS_1, the HR non-contacting portion NS_2, the HR contacting portion SE, the HR contacting portion SE_1, and the HR contacting portion SE_2 in the semiconductor memory device 1r may be respectively referred to as an “HR non-contacting portion NSr”, an “HR non-contacting portion NSr_1”, an “HR non-contacting portion NSr_2”, an “HR contacting portion SEr”, an “HR contacting portion SEr_1”, and an “HR contacting portion SEr_2”. FIG. 41 shows an example of a cross-sectional structure of the periphery of a contact plug CC in the HR non-contacting portion NSr according to the comparative example of the first embodiment. FIG. 41 is an enlarged view of an area that is the same as the area shown in FIG. 12.

The spacer CSPr differs from the spacer CSP (FIG. 9) mainly in terms of the features to be described below. The structure and configuration of the spacer CSPr do not depend on the location. That is, the spacer CSPr has a similar structure and configuration at each of the HR non-contacting portion NSr_1, the HR non-contacting portion NSr_2, the HR contacting portion SEr_1, and the HR contacting portion SEr_2. The spacer CSPr includes only a second spacer 82, and does not include a first spacer 81.

As shown in FIG. 41, the spacer CSPr covers the periphery of the conductor 80 in the xy plane, excluding a layer including the insulator 34 on an upper surface of the conductor 23 with which a lower surface of the conductor 80 is in contact. The HR non-contacting portion NSr includes a second spacer 82. The second spacer 82 covers a side surface of the conductor 80. A layer stack body is located on a side surface of the second spacer 82.

An HR contacting portion SEr (not illustrated) has a structure similar to the HR non-contacting portion NSr. That is, the HR contacting portion SEr includes a second spacer 82. The second spacer 82 covers a side surface of the conductor 80. Support pillars HR are located on a side surface of the second spacer 82. A layer stack body is located on a side surface of the support pillar HR deviated from the HR contacting portion SEr.

In the manufacturing process of the semiconductor memory device 1, a case has been described where, as an example, a contact hole CH in which a contact plug CC and a spacer CSP are to be formed has a columnar shape; however, the contact hole CH may in actuality, have a tapered shape due to the manufacturing technique.

In the case of the semiconductor memory device 1r, a spacer CSPr (second spacer 82) is formed on surfaces of the contact hole CH after processing at step S16. If the contact hole CH has a tapered shape, the second spacer 82 formed on a side wall of the contact hole CH may be formed to have a smaller thickness as the distance to the bottom of the contact hole CH decreases. If the second spacer 82 is formed with a small thickness, a current leak may occur between the contact plug CC and a word line WL that is in contact with the second spacer 82 with the small thickness. In the example of FIG. 41, a current leak may occur between a contact plug CC0 and a word line WL1 and/or WL2.

On the other hand, the spacer CSP includes an HR non-contacting portion NS_2. The HR non-contacting portion NS_2 is locally formed at a position corresponding to a space RP that has been formed by further recessing the insulators SM2 to SM3 from the contact hole CH in processing at step S17. That is, the spacer CSP is formed in the space RP extending in the xy plane by recessing the insulators SM2 to SM3. By forming the HR non-contacting portion NS_2 in the space RP extending in the xy plane, the spacer CSP ensures a margin in the xy plane. Since the spacer CSP has a margin in the xy plane, it is possible to prevent a current leak between the contact plug CC and the word line WL even if the contact hole CH has a tapered shape.

Moreover, in the case of the semiconductor memory device 1, since the thickness of the spacer CSP at the HR non-contacting portion NS_2 can be adjusted by adjusting an amount of recess of the insulators SM2 to SM3, it is possible to adjust the margin.

Here, a case will be assumed where the second spacer 82 is formed to have a larger thickness, as in the structure of the semiconductor memory device 1r, for the purpose of ensuring a margin in the xy plane. In this case, the margin could be ensured; however, the volume of the contact plug CC (conductor 80) is reduced, possibly hindering the function of the contact plug CC as a contact. Since the spacer CSP ensures a certain volume of the conductor 80 while ensuring a certain margin in the xy plane, it is possible to maintain the function of the contact plug CC as a contact.

In this manner, since the spacer CSP of the first embodiment includes an HR non-contacting portion NS_2, it is possible to prevent a current leak between the contact plug CC and the word line WL adjacent thereto with the HR non-contacting portion NS_2 interposed therebetween.

Moreover, with the spacer CSP of the semiconductor memory device 1 according to the first embodiment, it is possible to prevent the support pillar HR from being excessively etched at the time of etching of the bottom surface of the contact hole CH in processing at step S24. If the support pillar HR is excessively etched, the etching will be performed to a depth of the word line WL at a layer below the objective depth, possibly causing a current leak between the contact plug CC and the word line WL at the layer below the objective depth.

In the case of the semiconductor memory device 1r, for example, the spacer CSPr (second spacer 82) is formed on a surface of the contact hole CH after processing at step S16. The second spacer 82 formed at the bottom of the contact hole CH is removed by a step (referred to as “step S24r”) corresponding to step S24 at the spacer CSP.

In processing at step S24r, similarly to the processing at step S24, the second spacer 82 and the insulator 34 located at the bottom of the contact hole CH are removed by anisotropic etching, and thereby the conductor 23 is exposed.

Here, the total thickness of the second spacer 82 and the insulator 34 etched at step S24r is approximately 100 nm. If the amount of over-etching is set to, for example, 30%, a remaining film of approximately 30 nm is removed. However, there may be a case where the support pillar HR is excessively etched through the over-etching. The support pillar HR includes silicon oxide, similarly to the first spacer 81, the second spacer 82, and the insulator 34. Accordingly, the etching of the support pillar HR may not stop at a position flush with an upper surface of the conductor 23, and may advance to a lower layer.

If the support pillar HR is excessively etched, the etching may be performed to a depth of the word line WL below the objective depth. If the etching is performed to a depth of the word line WL below the objective depth, the conductor 80 may be brought into conduction with the word line WL below the objective depth after the conductor 80 is filled into the contact hole CH. That is, a current leak may occur between the contact plug CC and the word line WL below the objective depth.

On the other hand, the spacer CSP includes a first spacer 81 and a second spacer 82, which are two types of insulators with different etching rates. In processing at step S19, the second spacer 82 with a higher etching rate is removed, and the first spacer 81 with a lower etching rate remains. Accordingly, in the processing at step S24, the first spacer 81 and the insulator 34 are etched. Since the first spacer 81 is formed to have a small thickness, the total thickness of the first spacer 81 and the insulator 34 is, for example, approximately 20 nm. Accordingly, even if the amount of over-etching is set to 30%, the remaining film to be removed has a thickness on the order of 6 nm. It is thereby possible to prevent the case where the support pillar HR is excessively etched by over-etching to a depth of the word line WL below the objective depth, as in the semiconductor memory device 1r.

In this manner, since the spacer CSP of the first embodiment includes two types of insulators with different etching rates, it is possible to prevent a current leak between the contact plug CC and the word line WL below the objective depth.

With the spacer CSP of the semiconductor memory device 1 according to the first embodiment, it is possible to lay out the support pillars HR regardless of the disposition of the contact plugs CC. There may be a case where, for example, the support pillars HR of the semiconductor memory device 1r are excessively etched by over-etching, as described above. It is thus desirable that, in the semiconductor memory device 1r, the support pillars HR should not be provided directly below the contact plugs CC. That is, in the case of the semiconductor memory device 1r, a restriction may be imposed on the layout of the support pillars HR, depending on the disposition of the contact plugs CC.

On the other hand, with the semiconductor memory device 1, it is possible to prevent the support pillars HR from being excessively etched, as described above. That is, it is possible to lay out the support pillars HR without taking into consideration the risk of the support pillars HR being excessively etched. In other words, in the semiconductor memory device 1, the support pillars HR may be laid out regardless of the disposition of the contact plugs CC.

Specifically, the support pillar HR of the semiconductor memory device 1 according to the first embodiment may be provided at the center of (directly below) each contact plug CC in an xy plane view. Moreover, a layout may be adopted in which the support pillars HR are not in contact with a side surface of the spacer CSP. Furthermore, x-direction coordinates of two adjacent rows of support pillars HR may be substantially the same. An example of such support pillars HR will be described later in a modification.

With the semiconductor memory device 1 according to the first embodiment, it is possible to dispose the support pillars HR at a high density, regardless of the disposition of the contact plugs CC. With the semiconductor memory device 1 according to the first embodiment, in which the support pillars HR are disposed at a high density, it is possible, for example, to inhibit the shape of the structure from being collapsed in the processing at step 23.

Subsequently, with the spacer CSP of the semiconductor memory device 1 according to the first embodiment, it is possible to prevent the etchant from eroding the spacer CSP at the time of removing the insulators SM1 to SM3 in the processing at step S23.

The spacer CSP includes a first spacer 81 and a second spacer 82, which offer different etching rates, at the HR non-contacting portion NS_2. It is the first spacer 81 with a low etching rate that is in contact with the insulators SM1 to SM3. That is, it is the first spacer 81 that is in contact with the etchant during etching of the insulators SM1 to SM3.

On the other hand, in the case of the spacer CSPr, it is the second spacer 82 with a high etching rate that is in contact with the insulators SM1 to SM3. That is, it is the second spacer 82 that is in contact with the etchant during etching of the insulators SM1 to SM3.

As described above, the first spacer 81 subjected to an etchant (e.g., hydrofluoric acid) offers a low etching rate for silicon oxide, compared with the second spacer 82. The density of the element, for example, also relates to the level of the etching rate. The density of silicon oxide at the first spacer 81 is, for example, higher than the density of silicon oxide at the second spacer 82. Accordingly, the first spacer 81 subjected to an etchant offers a low etching rate not only for silicon oxide but also for silicon nitride, compared to the second spacer 82. That is, even if subjected to an etchant for etching the insulators SM1 to SM3, the first spacer 81 is not easily eroded, compared to the second spacer 82. With the spacer CSP described above, it is possible to effectively prevent the spacer CSP from being eroded by the etchant during etching of the insulators SM1 to SM3, compared to the spacer CSPr.

### <2> Modification of First Embodiment

In a semiconductor memory device 1 according to a first modification of the first embodiment, a first spacer 81 of a spacer CSP at an HR non-contacting portion NS_2 may have a bird's beak.

The semiconductor memory device 1 and the spacer CSP according to the first modification of the first embodiment may be respectively referred to as a “semiconductor memory device 1b” and a “spacer CSPb”. The HR non-contacting portion NS, the HR non-contacting portion NS_1, and the HR non-contacting portion NS_2 in the semiconductor memory device 1b may be respectively referred to as an “HR non-contacting portion NSb”, an “HR non-contacting portion NSb_1”, and an “HR non-contacting portion NSb_2”.

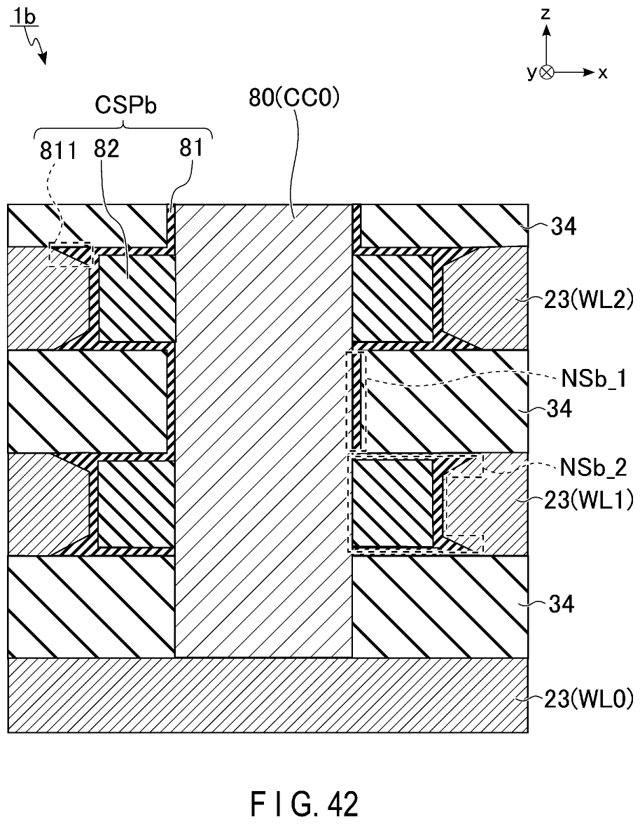

FIG. 42 shows an example of a cross-sectional structure of the periphery of a contact plug CC at the HR non-contacting portion NSb. FIG. 42 shows an area that is the same as that shown in FIG. 12. As shown in FIG. 42, the first spacer 81 of the HR non-contacting portion NSb_2 may have a bird's beak. The bird's beak may be hereinafter referred to as a “projecting portion 811”.

The first spacer 81 of the HR non-contacting portion NSb_2 may further include a projecting portion 811 extending along a layer direction (xy plane) at upper and lower ends in a layer including the conductor 23 in the z direction. The projecting portion 811 has a tapered shape that gets narrower from a side on which the conductor 80 is provided toward a side on which the conductor 23 is provided. In other words, the projecting portion 811 becomes thinner as the distance from the conductor 80 increases. The projecting portion 811 is located in the layer including the conductor 23, and is not located in a layer including the interlayer insulating film. With the projecting portion 811 formed in the layer including the conductor 23, the conductor 23 has a smaller thickness in an area close to the spacer CSPb than in an area distanced from the spacer CSPb, in the z direction. The projecting portion 811 is of the same material as the first spacer 81.

The projecting portion 811 may be formed on a side of the insulators SM1 to SM3 in the process of oxidizing silicon nitride with radials during formation of the first spacer 81.

The spacer CSPb may be referred to as, for example, a “spacer insulator”. The spacer insulator includes a projecting portion 811 that projects toward the conductor 23 at a portion provided between the conductor 23 and the conductor 80, and the projecting portion 811 extends along the xy plane at lower and upper ends (an end portion on one side and an end portion on the other side in the z direction) of the first layer including the conductor 23 in the z direction. The spacer insulator includes a first portion provided between the conductor 23 and the conductor 80, and a second portion provided between the insulator 34 and the conductor 80, and a thickness of the first portion in the xy plane intersecting the z direction is greater than a thickness of the second portion in the xy plane.

The support pillar HR may be referred to as, for example, a “pillar-shaped insulator”. The spacer insulator includes a first portion provided between the conductor 23 and the conductor 80 without a pillar-shaped insulator interposed between the conductor 23 and the spacer insulator, and a third portion provided between the pillar-shaped insulator and the conductor 80 so as to be in contact with the pillar-shaped insulator, and a thickness of the first portion in the xy plane intersecting the z direction is greater than a thickness of the third portion in the xy plane intersecting the z direction.

The semiconductor memory device 1b includes a spacer CSPb with a projecting portion 811, unlike the spacer CSP. Accordingly, the conductors 23 of the semiconductor memory device 1b are provided along the projecting portion 811. The portion of the conductor 23 provided along the projecting portion 811 has a structure chamfered by the projecting portion 811. With such a shape, the conductor 23 of the semiconductor memory device 1b may effectively suppress the concentration of an electric field at the time of application of a voltage, compared to the conductor 23 with a structure not including the projecting portion 811, as in the semiconductor memory device 1. Accordingly, with the semiconductor memory device 1b, it is possible to suppress concentration of an electric field at a portion at which the conductor 23 and the conductor 80 face each other, thereby improving the insulating properties between the conductor 23 and the conductor 80. The spacer CSPb of the semiconductor memory device 1b has been described with reference to FIG. 42, which shows a cross-sectional structure in the periphery of the contact plug CC at a layer including the conductor 23; however, the structure and function of the spacer CSPb at a layer including the conductor 24 is similar to that at the layer including the conductor 23.

As described above, the positions of a side surface on which the spacer CSP at the HR non-contacting portion NS_2 is in contact with the conductor 80 and a side surface on which the spacer CSP at the HR non-contacting portion NS_1 is in contact with the conductor 80 may be either aligned or not aligned in the xy plane. In a second modification of the first embodiment, an example in which positions of side surfaces are not aligned will be described.

The semiconductor memory device 1 and the spacer CSP according to the second modification of the first embodiment may be respectively referred to as a “semiconductor memory device 1c” and a “spacer CSPc”. Also, the HR non-contacting portion NS, the HR non-contacting portion NS_1, and the HR non-contacting portion NS_2 in the semiconductor memory device 1c may be respectively referred to as an “HR non-contacting portion NSc”, an “HR non-contacting portion NSc_1”, and an “HR non-contacting portion NSc_2”.

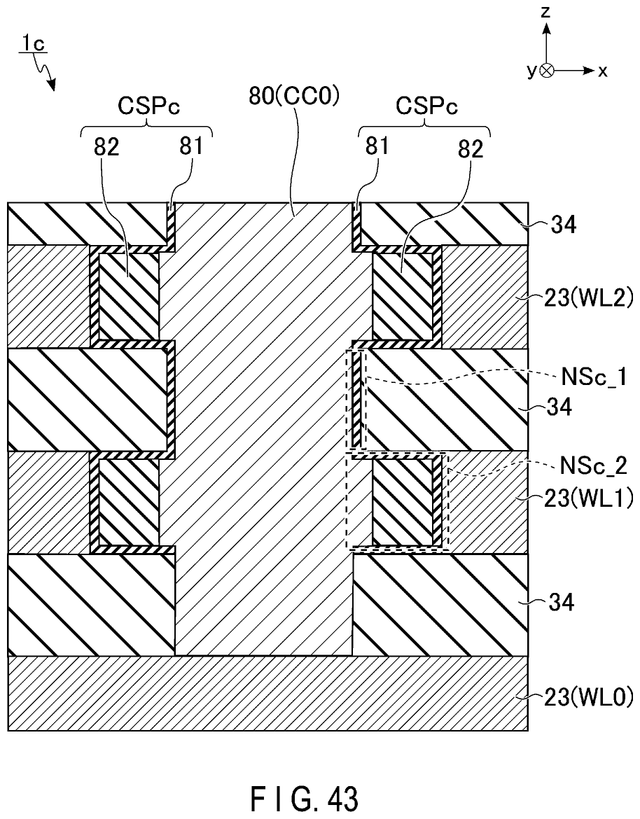

FIG. 43 shows an example of a cross-sectional structure of the periphery of a contact plug CC at the HR non-contacting portion NSc. FIG. 43 shows an area that is the same as that shown in FIG. 12. As shown in FIG. 43, a position of a side surface on which the spacer CSPc at the HR non-contacting portion NS_2 is in contact with the conductor 80 and a position of a side surface on which the spacer CSPc at the HR non-contacting portion NS_1 is in contact with the conductor 80 may be either aligned or not aligned in the xy plane. Specifically, the position of the side surface on which the spacer CSPc (second spacer 82) at the HR non-contacting portion NSc_2 is in contact with the conductor 80 is located at a position distanced from the center of the conductor 80, compared to a position of the side surface at which the spacer CSPc (first spacer 81) of the HR non-contacting portion NSc_1 is in contact with the conductor 80 in an xy plane view.

As described with reference to FIG. 29, in the processing at step S19, the second spacer 82 at the HR non-contacting portion NSc_2 may be etched as long as it maintains a thickness that ensures insulating properties between the contact plug CC and the word line WL in the xy plane. That is, the thickness of the second spacer 82 that remains in the end may be varied by adjusting an amount of etching. If the second spacer 82 is formed with a small thickness, the position of a side surface on which the second spacer 82 at the HR non-contacting portion NSc_2 is in contact with the conductor 80 is located at a position distanced from the center of the conductor 80, compared to a position of a side surface on which the first spacer 81 at which the HR non-contacting portion NSc_1 is in contact with the conductor 80 in an xy plane view.

That is, there may be a case where a surface at which the first spacer 81 at the HR non-contacting portion NSc_1 faces the conductor 80 is not located on an extension of a surface at which the second spacer 82 at the HR non-contacting portion NSc_2 faces the conductor 80. The conductor 80 in the first layer including the conductor 23 (or the conductor 24) has a length greater than a length of the conductor 80 in the second layer including the insulator 34, in the xy plane. Since the HR non-contacting portion NSc_1 and the HR non-contacting portion NSc_2 are alternately arranged in the z direction, a side surface on which the spacer CSPc faces the conductor 80 (a side surface along the z direction) has a cross-sectional shape similar to square waves.

As described above, with the spacer CSP of the semiconductor memory device 1 according to the first embodiment, it is possible to lay out the support pillars HR regardless of the disposition of the contact plugs CC. Accordingly, the support pillar HR of the semiconductor memory device 1 according to the first embodiment may be provided at the center of (directly below) each contact plug CC in an xy plane view. Moreover, a layout may be adopted in which the support pillars HR are not in contact with a side surface of the spacer CSP. In a third modification of the first embodiment, an example will be shown in which a support pillar HR is provided at the center of (directly below) each contact plug CC in an xy plane view, so as not to be in contact with a side surface of a spacer CSP.

The semiconductor memory device 1, the spacer CSP, and the support pillars HR according to the third modification of the first embodiment may be respectively referred to as a “semiconductor memory device 1d”, a “spacer CSPd”, and “support pillars HRd”.

Since the support pillar HRd is not in contact with a side surface of the spacer CSPd, the semiconductor memory device 1d does not include an HR contacting portion SE_1 or an HR contacting portion SE_2. In the semiconductor memory device 1d, the entirety of a side surface of the spacer CSPd forms an HR non-contacting portion NS_1 and an HR non-contacting portion NS_2. The HR non-contacting portion NS_1 and the HR non-contacting portion NS_2 in the semiconductor memory device 1d may be respectively referred to as an “HR non-contacting portion NSd_1” and an “HR non-contacting portion NSd_2”.

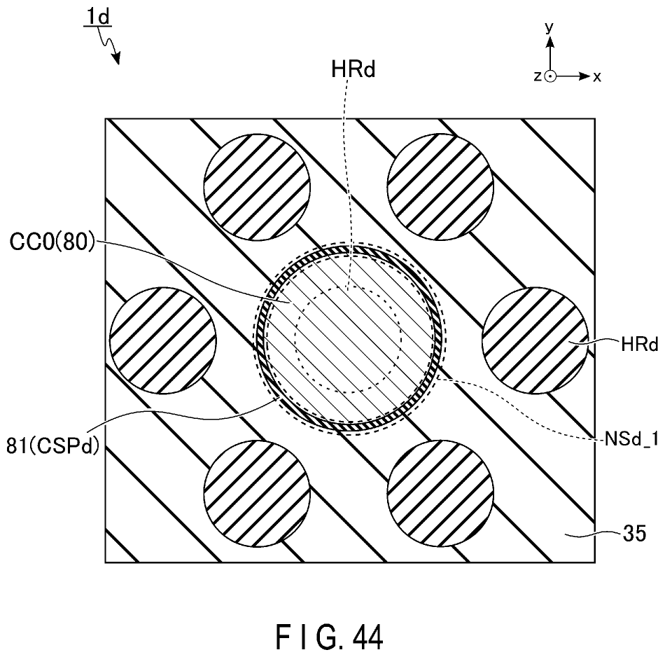

FIG. 44 shows an example of a cross-sectional structure of the periphery of the contact plug CC at the HR non-contacting portion NSd_1. FIG. 44 shows an area that is the same as that shown in FIG. 8. As shown in FIG. 44, the support pillar HRd is not in contact with a side surface of the spacer CSPd. An HR contacting portion SE_1 is not formed at a layer including the insulator 35 (or insulator 34) of the spacer CSPd, and the entirety of a side surface of the spacer CSPd forms the HR non-contacting portion NSd_1. One of the support pillars HRd is provided directly below the contact plug CC0.

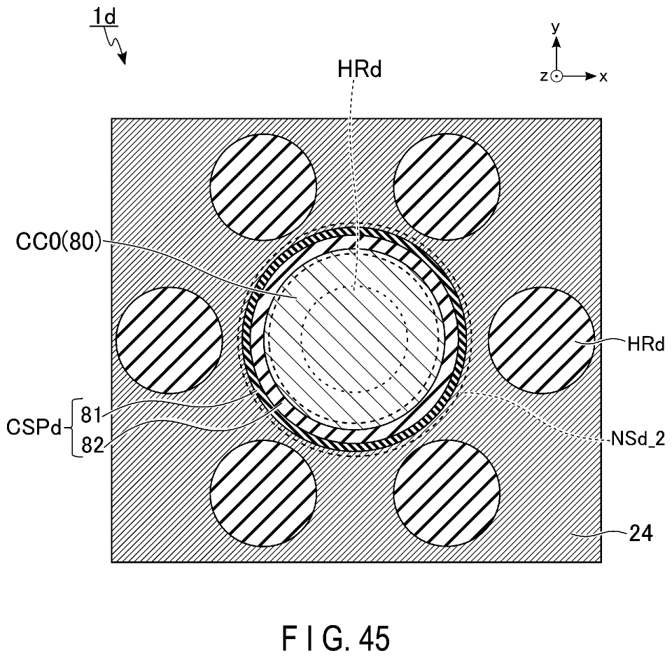

FIG. 45 shows an example of a cross-sectional structure of the periphery of the contact plug CC at the HR non-contacting portion NSd_2. FIG. 45 shows an area that is the same as that shown in FIG. 13. As shown in FIG. 45, in a layer including the conductor 23 (or the conductor 24) of the spacer CSPd, an HR contacting portion SE_2 is not formed, and the entirety of a side surface of the spacer CSPd forms the HR non-contacting portion NSd_2. The spacer CSPd at the HR non-contacting portion NSd_2 includes the second spacer 82. Accordingly, the spacer CSPd of the HR non-contacting portion NSd_2 in an xy plane view may have a greater outer diameter than the spacer CSPd of the HR non-contacting portion NSd_1.

As shown in FIGS. 44 and 45, one of the support pillars HRd is provided directly below the contact plug CC0. Even with such a layout of the support pillars HRd, it is possible to prevent the support pillars HRd from being excessively etched by over-etching in the processing at step S24, as described above. That is, it is possible to prevent a current leak between the contact plug CC and the word line WL below the objective depth.

As described above, a high dielectric constant insulator that functions as a block insulating film may be provided in the periphery of the conductors 22 to 24. In a fourth modification of the first embodiment, an example in which a high dielectric constant insulator 40 is provided in the periphery of the conductors 22 to 24 is shown.

The semiconductor memory device 1 and the conductors 22 to 24 according to the fourth modification of the first embodiment may be respectively referred to as a “semiconductor memory device 1e” and “conductors 22e to 24e”. Also, layers including the conductors 22 to 24 in the semiconductor memory device 1 may be respectively referred to as “stacked interconnect layers WLL22 to 24”.

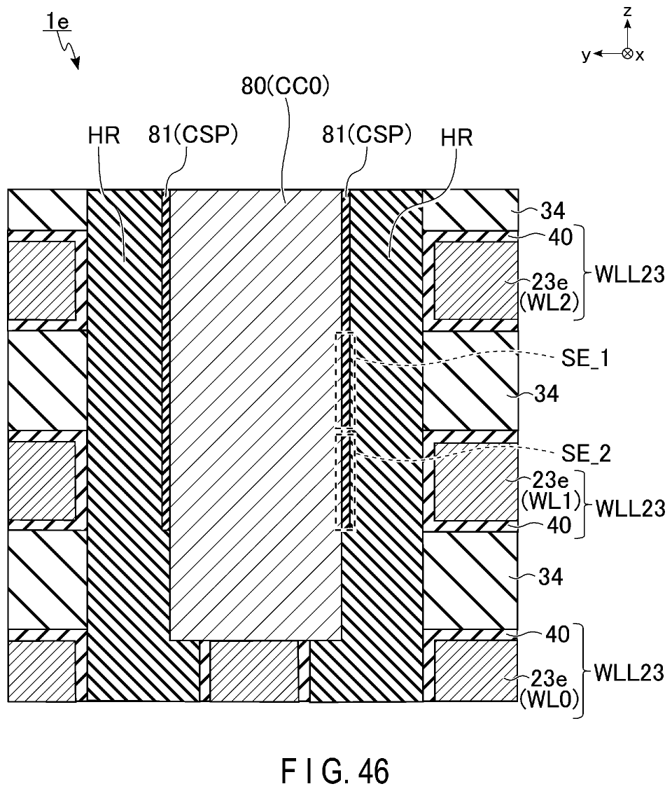

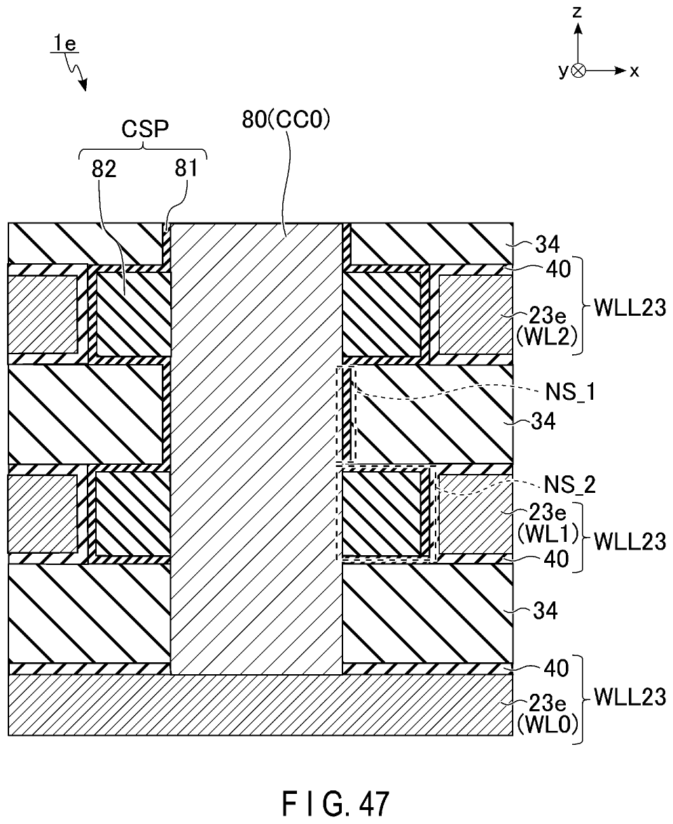

FIG. 46 shows an example of a cross-sectional structure of the periphery of a contact plug CC in an HR contacting portion SE according to a fourth modification of the first embodiment. FIG. 46 shows an area that is the same as that shown in FIG. 11. FIG. 47 shows an example of a cross-sectional structure of the periphery of the contact plug CC in an HR non-contacting portion NS according to the fourth modification of the first embodiment. FIG. 47 shows an area that is the same as that shown in FIG. 12.

As shown in FIGS. 46 and 47, in the fourth modification, the stacked interconnect layer WLL23 includes a high dielectric constant insulator 40 and a conductor 23e. The conductor 23e extends in the stacked interconnect layer WLL23. That is, the conductor 23e has a plate-like shape extending along, for example, the xy plane. The other features such as the functions and material of the conductor 23e are similar to those of the conductor 23.

The high dielectric constant insulator 40 covers the periphery of the conductor 23e in the stacked interconnect layer WLL23. Specifically, the high dielectric constant insulator 40 covers the periphery of the conductor 23e, except for a portion at which the conductor 23e is in contact with a lower surface of the conductor 80 and a portion at which the conductor 23e is in contact with the member SLT. That is, the high dielectric constant insulator 40 is located between the memory pillar MP and the support pillar HR and the conductor 23e. The high dielectric constant insulator 40 is located between the spacer CSP and the conductor 23e. The high dielectric constant insulator 40 is located between the interlayer insulating film and the conductor 23e. The high dielectric constant insulator 40 is not located between the lower surface of the conductor 80 and the conductor 23e. That is, the lower surface of the conductor 80 is in contact with the conductor 23e. The high dielectric constant insulator 40 may or may not be formed substantially uniformly.

The high dielectric constant insulator 40 functions as, together with a block insulator 55, a block insulating film. The high dielectric constant insulator 40 includes, for example, a metal oxide. The high dielectric constant insulator 40 includes, for example, aluminum oxide.

A method of manufacturing the semiconductor memory device 1e according to the fourth modification will be described below, in terms of the matters different from those of the method of manufacturing the semiconductor memory device 1 described above. Steps S23 and S24 in the method of manufacturing the semiconductor memory device 1e may be respectively referred to as steps “S23e” and “S24e”.

In the processing at step S23e, a high dielectric constant insulator 40 is formed along the space (stacked interconnect layers WLL22 to 24) from which the insulators SM1 to SM3 have been removed. Thereafter, a metal material is filled in the surface of the high dielectric constant insulator 40 and the remaining space, and conductors 22e to 24e are formed.

In processing at step S24e, after the first spacer 81 and the insulator 34 are removed at the bottom of the contact hole CH, the high dielectric constant insulator 40 is exposed. Exposed is a high dielectric constant insulator 40 that had been in contact with a lower surface of the removed insulator 34.

Thereafter, further etching is carried out via the contact hole CH, and a portion of the high dielectric constant insulator 40 that has been exposed at the bottom of the contact hole CH is removed. Thereby, the conductor 23e that had been in contact with a lower surface of the removed portion of the high dielectric constant insulator 40 is exposed to the bottom of the contact hole CH.

The stacked interconnect layer WLL23 according to the fourth modification has been described with reference to FIGS. 46 and 47; however, the stacked interconnect layer WLL22 and the stacked interconnect layer WLL24 are also similar to the stacked interconnect layer WLL23. The conductors 22 to 24 may have a structure of the conductors 22 to 24 in which a barrier metal material is included in the periphery of a metal material such as tungsten or molybdenum. In the case of, for example, the conductors 22e to 24e in which the high dielectric constant insulator 40 is provided in the periphery, a barrier metal material including a metal nitride, etc. may be disposed between the metal material such as tungsten or molybdenum and the high dielectric constant insulator 40 so as to be in contact with the high dielectric constant insulator 40.

### <3> Other Modifications, Etc.

The semiconductor memory device 1 according to the first embodiment may have a structure different from that of the above-described one. The structures described in the modifications of the first embodiment may be partly adopted, or may be combined.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a first conductor and a first insulator arranged in a first direction;
a second conductor extending in the first direction so as to penetrate the first conductor and the first insulator;
a memory pillar extending in the first direction so as to penetrate the first conductor and the first insulator and including a semiconductor;
a second insulator provided between the first conductor and the second conductor; and
a third insulator including a first portion provided between the second insulator and the first conductor, a portion provided on a surface on one side of the second insulator in the first direction, and a portion provided on a surface on the other side of the second insulator in the first direction, wherein
the third insulator offers an etching rate smaller than an etching rate of the second insulator.

2. The semiconductor memory device according to claim 1, further comprising:
a third conductor provided on the one side of the first conductor and the first insulator in the first direction, wherein
the memory pillar penetrates the third conductor, and
a surface on the one side of the second conductor in the first direction is in contact with a surface on the other of the third conductor in the first direction.

3. The semiconductor memory device according to claim 1, wherein
the third insulator further includes a second portion provided between the first insulator and the second conductor, and
a distance between the first portion and the second conductor in a direction intersecting the first direction is greater than a distance between the second portion and the second conductor in the direction intersecting the first direction.

4. The semiconductor memory device according to claim 1, further comprising:
a fourth insulator extending in the first direction so as to penetrate the first conductor and the first insulator, wherein
the third insulator further includes a third portion provided between the fourth insulator and the second conductor so as to be in contact with the fourth insulator, and a portion provided between the second insulator and the fourth insulator, and
a distance between the first portion and the second conductor in a direction intersecting the first direction is greater than a distance between the third portion and the second conductor in the direction intersecting the first direction.

5. The semiconductor memory device according to claim 3, wherein
a surface at which the second portion faces the second conductor is located on an extension of a surface at which the second insulator faces the second conductor.

6. The semiconductor memory device according to claim 3, wherein
a surface at which the second portion faces the second conductor is not located on an extension of a surface at which the second insulator faces the second conductor.

7. The semiconductor memory device according to claim 6, wherein
a length of the second conductor in a first layer including the first conductor in the direction intersecting the first direction is greater than a length of the second conductor in a second layer including the first insulator in the direction intersecting the first direction.

8. The semiconductor memory device according to claim 4, wherein
the second insulator is not provided between the third portion and the second conductor.

9. The semiconductor memory device according to claim 8, wherein
the second insulator is not provided in a second layer including the first insulator.

10. The semiconductor memory device according to claim 4, wherein
the first insulator, the second insulator, the third insulator, and the fourth insulator include a silicon oxide.

11. The semiconductor memory device according to claim 1, wherein
the etching rate is an etching rate for hydrogen fluoride.

12. A semiconductor memory device, comprising:
a first conductor and a first insulator arranged in a first direction;
a second conductor extending in the first direction so as to penetrate the first conductor and the first insulator;
a third conductor provided on one side of the first conductor and the first insulator in the first direction;
a memory pillar extending in the first direction so as to penetrate the first conductor, the first insulator, and the third conductor, and including a semiconductor; and
a spacer insulator covering a periphery of the second conductor in a direction intersecting the first direction, wherein
a surface on the one side of the second conductor in the first direction is in contact with a surface on the other side of the third conductor in the first direction,
the spacer insulator includes a projecting portion projecting toward the first conductor at a portion provided between the first conductor and the second conductor, and
the projecting portion extends along the direction intersecting the first direction at an end portion on the one side and an end portion on the other side of a first layer including the first conductor in the first direction.

13. The semiconductor memory device according to claim 12, wherein
the spacer insulator includes a first portion provided between the first conductor and the second conductor, and a second portion provided between the first insulator and the second conductor, and
a thickness of the first portion in the direction intersecting the first direction is greater than a thickness of the second portion in the direction intersecting the first direction.

14. The semiconductor memory device according to claim 12, further comprising:
a pillar-shaped insulator extending in the first direction so as to penetrate the first conductor, the first insulator, and the third conductor, wherein
the spacer insulator includes a first portion provided between the first conductor and the second conductor without the pillar-shaped insulator being interposed between the first portion and the first conductor, and a third portion provided between the pillar-shaped insulator and the second conductor so as to be in contact with the pillar-shaped insulator, and
a thickness of the first portion in the direction intersecting the first direction is greater than a thickness of the third portion in the direction intersecting the first direction.

15. The semiconductor memory device according to claim 12, wherein
a thickness of the first conductor in the first direction is smaller in an area close to the spacer insulator than an area distanced from the spacer insulator.

16. The semiconductor memory device according to claim 15, wherein
the projecting portion has a tapered shape that gets narrower from a side on which the second conductor is provided toward a side on which the first conductor is provided.

17. The semiconductor memory device according to claim 16, wherein
the projecting portion is not located in a layer including the first insulator.

18. The semiconductor memory device according to claim 13, wherein
a surface at which the second portion faces the second conductor is located on an extension of a surface at which the first portion faces the second conductor.

19. The semiconductor memory device according to claim 13, wherein
a surface at which the second portion faces the second conductor is not located on an extension of a surface at which the first portion faces the second conductor, and
a length of the second conductor in the first layer in the direction intersecting the first direction is greater than a length of the second conductor in a second layer including the first insulator in the direction intersecting the first direction.

20. The semiconductor memory device according to claim 13, wherein
the spacer insulator includes a second insulator and a third insulator,
the first portion includes the second insulator and the third insulator,
the second portion includes the third insulator and does not include the second insulator,
the second insulator is provided between the first conductor and the second conductor,
the third insulator includes a portion provided between the second insulator and the first conductor, a portion provided on a surface on the one side of the second insulator in the first direction, and a portion provided on the other side of the second insulator in the first direction, and
the third insulator offers an etching rate for hydrogen fluoride smaller than an etching rate for hydrogen fluoride of the second insulator.
